(19) United States
(12) Patent Application Publication
(10) Pub. No.: US 2025/0265391 A1
(43) Pub. Date: Aug. 21, 2025

(54) MACHINE LEARNING-ASSISTED RATIONAL DESIGN OF SEPARATION MEMBRANES

(71) Applicant: GEORGIA TECH RESEARCH CORPORATION, Atlanta, GA (US)

(72) Inventors: Yongsheng CHEN, Atlanta, GA (US); Haiping GAO, Atlanta, GA (US); Yuhang HU, Atlanta, GA (US); Guanghui LAN, Atlanta, GA (US); Yao XIE, Atlanta, GA (US); Wenlong ZHANG, Atlanta, GA (US)

(21) Appl. No.: 18/856,463

(22) PCT Filed: Apr. 13, 2023
(86) PCT No.: PCT/US2023/018534

§ 371 Date: Oct. 11, 2024

Related U.S. Application Data
(60) Provisional application No. 63/330,425, filed on Apr. 13, 2022.

(51) Int. Cl. G06F 30/27; G06F 30/28

(52) U.S. Cl. CPC G06F 30/27; G06F 30/28

(57) ABSTRACT

An ML-assisted framework is disclosed that can guide the design of fit-for-purpose separation membranes for resource recovery and clean water production from wastewaters. Approaches and methodologies for executing the work include the integrated components: 1) ML-assisted new polymer screening; 2) development of an interpretable ML model for membrane properties prediction; 3) mechanistic constitutive model; 4) development of a statistical ML model with a combination of proper regularization for membrane performance prediction; 5) separation membrane fabrication and evaluation.

### RELATED APPLICATIONS

This PCT application claims priority to, and the benefit of, U.S. Provisional Patent Application No. 63/330,425, filed Apr. 13, 2022, entitled “Machine Learning-Assisted Rational Design of Separation Membranes,” which is hereby incorporated by reference herein in its entirety.

### GOVERNMENT LICENSE RIGHTS

This invention was made with government support under grant number 2018-68011-28371 awarded by the U.S. Department of Agriculture. The government has certain rights in the invention.

### BACKGROUND

Water scarcity is a global issue. Membrane separation technology can harvest clean and safe water from unconventional water resources (e.g., seawater, brackish water, and wastewater) in a sustainable manner.

Conventional water membrane technology is often based on a range of synthetic membranes with various functions made from polymers or inorganic materials or mixtures thereof. To date, synthetic membranes, including microfiltration (MF), ultrafiltration (UF), nanofiltration (NF), and reverse osmosis (RO)) have been developed for water/wastewater treatment. Of these, MF and UF have become major technologies for water treatment from non-saline sources, and pretreatment for RO processes in wastewater treatment and in membrane bioreactors.

With the development of thin-film composite polyamide (TFC-PA) membranes, freshwater can now be efficiently produced through NF and RO from saline water (e.g., seawater and brackish water), desalination, and wastewater reuse. Membrane separation performance is often defined by membrane selectivity, i.e., quantifying the extent to which the targeted solutes are separated from the other solutes of aqueous solutions. While membrane desalination requires separating all solutes from feed water, precise solute separation often refers to the separation of solutes from each other, that is, having a very high rejection for some species and a very low rejection for others. Therefore, there is a desire and benefit to designing performance-targeted separation membranes with “fit-for-purpose” selectivity.

Membrane fabrication can be a complex and multidimensional process that can involve the selection of membrane materials and the optimization of fabrication conditions from an infinite or very large candidate space. Current membrane development is based on exhaustive experimental investigations by screening procedures that result in heavy development costs and time. In addition, over the past few decades, advances in the development of polymer-based membrane materials have been limited, greatly relying on empirical approaches. Switching the trial-and-error fabrication process (e.g., exploring new membrane materials with optimal properties and searching for numerous combinations of materials, fabrication conditions, and operational settings) to a more efficient and non-trial-based membrane design strategy remains an open challenge.

Recent studies have applied data-driven models such as artificial neural network (ANN) and tree-based ML models for designing thin film nanocomposite (TFN) membranes and predicting TFC-PA membrane performance in reverse osmosis (RO), NF and organic solvent nanofiltration.

There are nevertheless benefits to improving the design of new membrane materials as well as separation membranes.

### SUMMARY

An ML-assisted separation membrane design framework is disclosed that integrates the selection of membrane materials, membrane fabrication conditions, and membrane properties to predict the separation performance of any new separation membranes and to guide the rational design of next-generation membrane materials and “fit-for-purpose” separation membranes in a time-efficient and cost-effective way.

The exemplary method can involve the collection of all fabrication parameters, membrane properties, and membrane performance indicators, e.g., that could be found in the literature published from the year 2000 to the year 2020, to develop more reliable ML models. The exemplary method can then train the ML algorithm using a training dataset (which is part of the available dataset) and test its predictions on the remaining dataset. This validated model can then predict the rejection behavior of a large body of monomers that have been synthesized to date (˜2000), but which have not been experimentally tested in this context. ML appears to be a powerful method to predict (and hence design) new materials that are optimal for a given application, particularly with limited sets of experimental data.

In addition, an ML-assisted framework is disclosed that can guide the design of fit-for-purpose separation membranes for resource recovery and clean water production from wastewater. Approaches and methodologies for executing include the following integrated components: 1) ML-assisted new polymer screening; 2) development of an interpretable ML model for membrane properties prediction; 3) mechanistic constitutive model; 4) development of a statistical ML model with a combination of proper regularization for membrane performance prediction; 5) separation membrane fabrication and evaluation.

In some aspects, the techniques described herein relate to a method to predict candidate separation membranes having a set of desired polymer membrane properties including: (a) retrieving one or more datasets of experimentally measured (e.g. from a database, scraping publications, or locally performed experiments) separation membrane properties, fabrication conditions, and operational conditions and related molecular descriptions (e.g. molecular fingerprint, molecular descriptor, molecular image, and molecular graph); (b) categorizing each entry of the dataset as one of a set of meaningful constraints (e.g. fabrication conditions, operational conditions, and membrane property, monomer selection); (c) encoding the categorized dataset for use in a machine learning model; (d) screening one or more algorithms for an optimal machine learning model, wherein screening includes training a test machine learning model with one or more algorithms for encoding, machine learning, and feature scaling on a subset of the one or more datasets, and validating the trained test machine learning model by cross-validation on the trained test machine learning model on the subset of the one or more datasets; (e) choosing an optimal machine learning model, wherein the optimal test machine learning model is defined by a coefficient of determination; (f) optimizing hyperparameters of the optimal machine learning model using Bayesian optimization, wherein an optimization target is the set of desired polymer membrane properties; (g) retraining the optimal machine learning model on the subset of the one or more datasets; and (f) running the retrained, optimal machine learning model on another subset of the one or more datasets to predict candidate separation membranes having a set of desired polymer membrane properties.

In some aspects, the techniques described herein relate to a method, further including: (g) computing Shapely values for the set of desired membrane properties on the related molecular descriptions; and (h) displaying the computed Shapely values.

In some aspects, the techniques described herein relate to a method, wherein the one or more datasets include effective separation membrane properties under real operation conditions generated from the mechanistic constitutive model as input variables.

In some aspects, the techniques described herein relate to a method, wherein the related molecular description is a Morgan fingerprint and is related to a monomer of the polymer membrane.

In some aspects, the techniques described herein relate to a system including: a processor; and a memory having instructions stored thereon, wherein the execution of the instructions by the processor causes the processor to: (a) retrieve one or more datasets of experimentally measured (e.g. from a database, scraping publications, or locally performed experiments) separation membrane properties, fabrication conditions, and operational conditions and related molecular descriptions (e.g. molecular fingerprint, molecular descriptor, molecular image, and molecular graph); (b) categorize each entry of the dataset as one of a set of meaningful constraints (e.g. fabrication conditions, operational conditions, and membrane property, monomer selection); (c) encode the categorized dataset for use in a machine learning model; (d) screen one or more algorithms for an optimal machine learning model, wherein screening includes training a test machine learning model with one or more algorithms for encoding, machine learning, and feature scaling on a subset of the one or more datasets, and validating the trained test machine learning model by cross-validation on the trained test machine learning model on the subset of the one or more datasets; (e) choose an optimal machine learning model, wherein the optimal test machine learning model is defined by a coefficient of determination; (f) optimize hyperparameters of the optimal machine learning model using Bayesian optimization, wherein an optimization target is the set of desired polymer membrane properties; (g) retrain the optimal machine learning model on the subset of the one or more datasets; and (f) run the retrained, optimal machine learning model on another subset of the one or more datasets to predict candidate separation membranes having a set of desired polymer membrane properties.

In some aspects, the techniques described herein relate to a system, further including: (g) computing Shapely values for the set of desired membrane properties on the related molecular descriptions; and (h) displaying the computed Shapely values.

In some aspects, the techniques described herein relate to a system, wherein the execution of the instructions by the processor further causes the processor to: execute a mechanistic constitutive model (physics-based with input parameters, e.g., monomer structure, additives, time and temperature of polymerization) of the membrane material to predict/estimate its effective properties under testing or operating conditions.

In some aspects, the techniques described herein relate to a system, wherein the execution of the instructions by the processor further causes the processor to: execute the optimized machine learning model (e.g., tree-based models) to predict/estimate membrane performances.

In some aspects, the techniques described herein relate to a non-transitory computer readable medium having instructions stored thereon, wherein the execution of the instructions by the processor causes the processor to: (a) retrieve one or more datasets of experimentally measured separation membrane properties, fabrication conditions, and operational conditions and related molecular descriptions; (b) categorize each entry of the dataset as one of a set of meaningful constraints; (c) encode the categorized dataset for use in a machine learning model; (d) screen one or more algorithms for an optimal machine learning model, wherein screening includes training a test machine learning model with one or more algorithms for encoding, machine learning, and feature scaling on a subset of the one or more datasets, and validating the trained test machine learning model by cross-validation on the trained test machine learning model on the subset of the one or more datasets; (e) choose an optimal machine learning model, wherein the optimal test machine learning model is defined by a coefficient of determination; (f) optimize hyperparameters of the optimal machine learning model using Bayesian optimization, wherein an optimization target is the set of desired polymer membrane properties; (g) retrain the optimal machine learning model on the subset of the one or more datasets; and (f) run the retrained, optimal machine learning model on another subset of the one or more datasets to predict candidate separation membranes having a set of desired polymer membrane properties.

In some aspects, the techniques described herein relate to a non-transitory computer readable medium, further including the executed.

In some aspects, the techniques described herein relate to a non-transitory computer readable medium, wherein the execution of the instructions by the processor further causes the processor to: execute a mechanistic constitutive model of the membrane material to predict/estimate its effective properties under testing or operating conditions.

In some aspects, the techniques described herein relate to a non-transitory computer readable medium, wherein the execution of the instructions by the processor further causes the processor to: execute the optimized machine learning model to predict/estimate membrane performances.

In some aspects, the techniques described herein relate to a non-transitory computer readable medium, wherein the optimized machine learning model employs effective membrane properties under real operation conditions generated from the mechanistic constitutive model as input variables.

In some aspects, the techniques described herein relate to the system or non-transitory computer readable medium of any one of the above claims, wherein the separation membrane are employed for resource recovery from wastewater.

### BRIEF DESCRIPTION OF DRAWINGS

The skilled person in the art will understand that the drawings described below are for illustration purposes only.

FIG. 1 shows a schematic of the general steps to guide polymer material selection using the ML-assisted framework.

FIG. 2 shows an association of the ML-based framework, including the machine learning model and Bayesian optimization, input data—in this example, water/Na2So4 selectivity versus water permeability for a set of materials—and the prediction versus the experimental results—in this example, predicted salt rejection versus actual salt rejection.

FIG. 3 shows (a) the upper-bound correlation of selectivity versus permeability for water/NaCl separation of polyamide (PA)-based thin-film composite (TFC) NF membrane and (b) an example of the formation of a PA layer with piperazine (PIP) serving as the amine monomer in the aqueous phase, and trimesoyl chloride (TMC) as acyl chloride in the organic phase on a porous substrate.

FIG. 4 Correlation of experimental results with predicted values. (a) Water permeability dataset and (b) salt rejection dataset. Na2SO4, MgSO4, MgCl2, CaCl2), LiCl, and NaNO3 were used for salt rejection tests. The fabricated membranes were named from 1 to 10.

FIG. 5 shows SHAP plots used to interpret the models for (a) the contribution of fabrication conditions to water permeability in the training dataset and (b) the contribution of fabrication conditions to salt rejection in the training dataset.

FIG. 6 Atomic groups serving as positive contributors. (a) Water permeability and (b) salt rejection. The unlabeled blue dots represent carbon atoms. Feature number denotes the feature position in the Morgan fingerprint vector. Atoms are colored by blue dots. The gray lines represent the bonds that are not included in the features.

FIG. 7 Identification of optimal combinations from Bayesian optimization. (a) Predicted results with Group 1 and Group 2 monomers for water/Na2SO4 selectivity versus water permeability. (b) Predicted values from identified combinations and the corresponding experimental performance. (c) Predicted results with Group 1 and Group 2 monomers for water/Na2SO4 selectivity versus water permeability. (d) Predicted values from identified combinations and corresponding experimental performance. The axes are logarithmic base10. Predicted values are marked with squares, and experimental results are denoted with triangles. The sets of fabrication conditions were differentiated by color. Predicted values and their corresponding experimental results were illustrated in the same color. For Na2SO4 rejection, tests are numbered from 1 to 6, and for NaCl rejection, tests are numbered between 1 and 2. Likewise, each prediction # corresponds to the same test number # when comparing membrane performance; p stands for prediction, and t stands for test.

FIG. 8 shows prediction results of the ML models for each target: (a) water permeability, (b) removal efficiency, (c) flux decline ratio, (d) flux recovery ratio, and (e) reversible fouling ratio.

FIG. 9 shows prediction performance of the ML model for each membrane property: (a) prediction performance with experimental validation of the overall porosity, (b) prediction performance with experimental validation of the mean pore radius, and (c) prediction performance with experimental validation of the contact angle.

FIG. 10 shows SHAP plot for water permeability based on ML models (a) without membrane properties and (b) with membrane properties. For panel a, the model was developed by using fabrication conditions as input features and water permeability as the target, while for panel b, the model was developed by using fabrication conditions combined with membrane properties as input features and water permeability as the target. A_number (e.g., A_5) denotes the encoder for the category feature (i.e., the type of additive). The feature number (e.g., fp_45) stands for the feature position in the Morgan fingerprint vector.

FIG. 11 shows Shapley values of additive loading (A_wt %) and polymer content (P_wt %) for each of the membrane performance indices: (a) water permeability, (b) removal efficiency, (c) flux decline ratio, (d) flux recovery ratio, and (e) reversible fouling ratio.

FIG. 12 shows SHAP plots for ML models on membrane properties: (a) mean pore size, (b) overall porosity, (c) contact angle, and (d) Shapley values of A_wt % for each of the membrane properties. A_number (e.g., A_2) denotes the encoder for the category feature (i.e., the type of additive). The feature number (e.g., fp_1654) denotes the feature position in the Morgan fingerprint vector.

FIG. 13 shows an illustrative computer architecture for use in implementing the machine learning-base framework.

### DETAILED SPECIFICATION

To facilitate an understanding of the principles and features of various embodiments of the present invention, they are explained hereinafter with reference to their implementation in illustrative embodiments.

An ML-assisted framework is disclosed that can guide the design of fit-for-purpose separation membranes for resource recovery and clean water production from wastewater. Approaches and methodologies for executing the work will start with the following integrated components: 1) ML-assisted new polymer screening; 2) development of an interpretable ML model for membrane properties prediction; 3) mechanistic constitutive model; 4) development of a statistical ML model with a combination of proper regularization for membrane performance prediction; 5) separation membrane fabrication and evaluation.

### Component #1 Machine-Learning-Assisted New Polymer Screening

A challenge in synthesizing next-generation separation membranes is the rational design of advanced polymers without resorting to empirical experimentation. To select new polymers with high separation performance, the design should cross the upper bound that defines the empirically determined state-of-the-art membrane performance in permeability and selectivity.

The disclosed ML-based methods (e.g., linear and generalized linear models, neural networks, trees, and random forest) can be used to guide the selection and design of optimal polymers. Literature-reported membrane permeability and salt selectivity data published between 2000 and 2020 can be stored for the ML model training database (e.g., validation, test and unseen data). A fingerprinting algorithm can be used where polymer descriptors (e.g., atoms, repeat units, chemical connectivity in repeat units, etc.) are translated into “fingerprints” to serve as ML inputs [14].

The disclosed ML model can be created with the specific goal of quickly characterizing salt selectivity for an extremely large set of polymers and then posteriori correlating high-performance materials with common functional groups and bond linkages, which allows a researcher or engineer to screen which chemistries and structures of the polymers are worth experimental observation.

The ML model can be applied to screen polymers, which have already been synthesized and, e.g., can be downloaded from the National Institute for Materials Science (NIMS) Materials database [15]. The selected polymers (with acceptable permeability and selectivity towards salts) can serve as a polymer database for the data-driven model, e.g., created in Component #2.

The exemplary framework described herein is readily amenable to an inverse design approach. Namely, the approach can be used to design polymers with the desired combination of permeability and selectivity for a salt pair by constructing the optimal fingerprint vectors.

### Component #2: Interpretable ML Model for Membrane Properties Prediction

Separation performance of membranes is highly dependent on their properties (e.g., membrane pore radius, pore size distribution, surface potential, and surface hydrophilicity, etc.). To predict intrinsic membrane properties, an interpretable machine learning model can be implemented, accounting for dozens of fabrication parameters as predictor variables (e.g., monomer structure, additives, time and temperature of polymerization, etc.). The exemplary method can achieve interpretability of the ML model in pre-defined settings through (1) incorporating meaningful constraints; (2) selecting and identifying the most important variables in the predictive model through various variable selection techniques (such as graphs or hierarchical regularizers) [16, 17]. Before model training, literature-sourced datasets may be evaluated through a feature engineering process to identify variable correlations. Such prior domain knowledge could be valuable, and may be incorporated, e.g., into the construction of graphs or hierarchical regularizers. When the model meets the training criteria, the Shapley value may be calculated to rank the importance of each predictor variable, and generalization ability may be evaluated to ensure meaningful model predictions. With the established relationship of the membrane fabrication process and membrane properties from this model, the exemplary method may be able to identify the most significant synthesis parameters and predict intrinsic membrane properties with the designed synthesis parameters without conducting wet-bench experiments.

### Component #3: Mechanistic Constitutive Model

The intrinsic membrane properties (e.g., permeability, pore size, and charge density) cannot be directly translated to the properties of the membrane under real operating conditions. The membrane deforms under pressure, and thus the effective pore size may change. The membrane microstructures may also evolve under different realistic conditions. The effective properties of the membrane that are related to its performance in water filtration are also related to the macroscopic size and shape of the membrane, which varies across subsets in literature data. To account for these discrepancies, a mechanistic constitutive model may be employed for the membrane material to predict its effective properties under testing or operating conditions, which can be further applied as described in Component #4. The model may be physics-based with input parameters from Example #2, including the crosslink density, pore size, and charge density to predict its effective pore size, distribution, and charge density under real operating or testing conditions and geometries.

Component #4: Development of a Statistical ML Model with Combination of Graph or Hierarchical Regularization for Membrane Performance Prediction

To provide theoretical guidance for yielding optimal membrane fabrication protocols to performance-targeted separation membranes, a statistical IL model, such as tree-based models, may be employed to predict membrane performances. In addition to membrane properties, membrane performance towards different solutes is closely related to solutes' features (e.g., hydration radius, charge density, hydration-free energy, etc.). To achieve more accurate predictions with rationality for membrane performance, the model may employ the effective membrane properties under real operation conditions (as simulated by Component #3) as input variables. Further, features of diverse solutes will be extracted from the literature as predictor variables for the versatile application of the model to different separation targets. In such an application, the dimensionality will be significantly increased, and there will be possible issues raised by limited data availability for a specific separation target—model development may suffer from data sparsity. To address this issue, graph or tree regularizer functions are introduced to lower the dimensions [18]. With the established relationship of membrane properties, solute features, and membrane performance from this versatile model, the performance of the membranes with desired membrane properties under different operational conditions in various resource recovery applications are predicted. Moreover, the established relationship will provide insights into the fundamental mass transport mechanisms.

### Component #5: Performance-Targeted Separation Membrane Fabrication and Evaluation

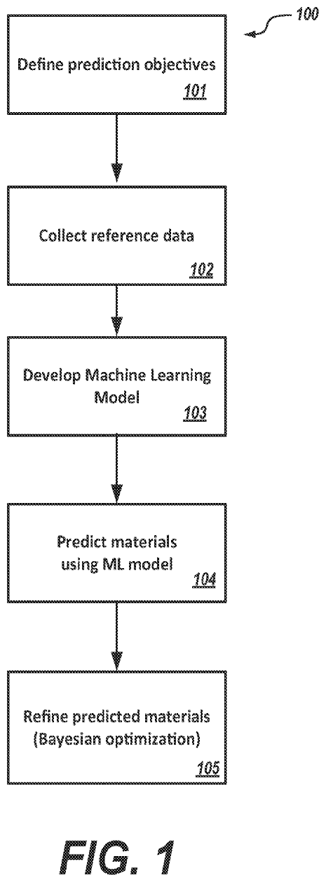

To determine the practical implementation of this framework, NF membranes can be synthesized and evaluated via bench-scale experiments to evaluate nutrient recovery performance (such as N and P) from wastewater starting with the selected set of input parameters with predicted performance falling within an acceptable range. If the predicted performance shows an unsatisfactory agreement with the experimental results, the readjustment of parameters in Component #2 (as shown in FIG. 1) can continue. The experiments can serve as a testbed for data-driven model optimization.

An embodiment of the method 100 to predict candidate separation membranes having a set of desired polymer membrane properties is exemplified in FIG. 1. A first step comprises defining the problem and objectives 101 (high permeability and rejection) which can include defining the properties and characteristics that are desired for the material and the constraints needed to adhere to, such as budget or manufacturing process requirements. A second step may comprise collecting reference data that meet the defined criteria 102 that may be one or more datasets of experimentally measured (e.g., from a database, scraping publications, or locally performed experiments) separation membrane properties, fabrication conditions, and operational conditions and related molecular descriptions (e.g., molecular fingerprint, molecular descriptor, molecular image, and molecular graph).

A third step of the method, developing the machine learning model 103, may comprise the intermediate steps of (a) categorizing each entry of the dataset as one of a set of meaningful constraints (e.g., fabrication conditions, operational conditions, and membrane property, monomer selection), (b) encoding the categorized dataset for use in a machine learning model, (c) screening one or more algorithms for an optimal machine learning model, wherein screening comprises training a test machine learning model with one or more algorithms for encoding, machine learning, and feature scaling on a subset of the one or more datasets, and validating the trained test machine learning model by cross-validation on the trained test machine learning model on the subset of the one or more datasets, (d) choosing an optimal machine learning model, wherein the optimal test machine learning model is defined by a coefficient of determination.

A fourth step of the method, predicting materials using Bayesian optimization 104, may comprise optimizing parameters of the optimal machine learning model using Bayesian optimization, wherein an optimization target is the set of desired polymer membrane properties. Bayesian optimization is a technique for finding the optimal set of parameters for a given objective function. In this case, the objective function would be the predicted material properties based on the desired criteria. Bayesian optimization can be used to explore the space of possible polymer materials and identify the best material candidates that meet the desired criteria.

A fifth step of the method, refining predicted material properties using Bayesian optimization 105, may comprise evaluating the recommended materials using additional criteria, such as manufacturability, cost, toxicity, and environmental impact. Once a polymer material is selected, it can be further optimized using Bayesian optimization to refine its properties by retraining the optimal machine learning model on the subset of the one or more datasets and running the retrained, optimal machine learning model on another subset of the one or more datasets to predict candidate separation membranes having a set of desired polymer membrane properties.

### EXPERIMENTAL RESULTS AND EXAMPLES

### Example: Polyamide-Based Thin-Film Composite Nanofiltration Membrane

A study was conducted to develop an inverse membrane design strategy that applies Bayesian optimization on a constructed ML model, which supports: (1) the discovery of unexplored monomers and (2) the precise identification of optimal monomer/fabrication condition combinations across an infinite space by understanding relationships between monomer structures, fabrication conditions, and membrane performance.

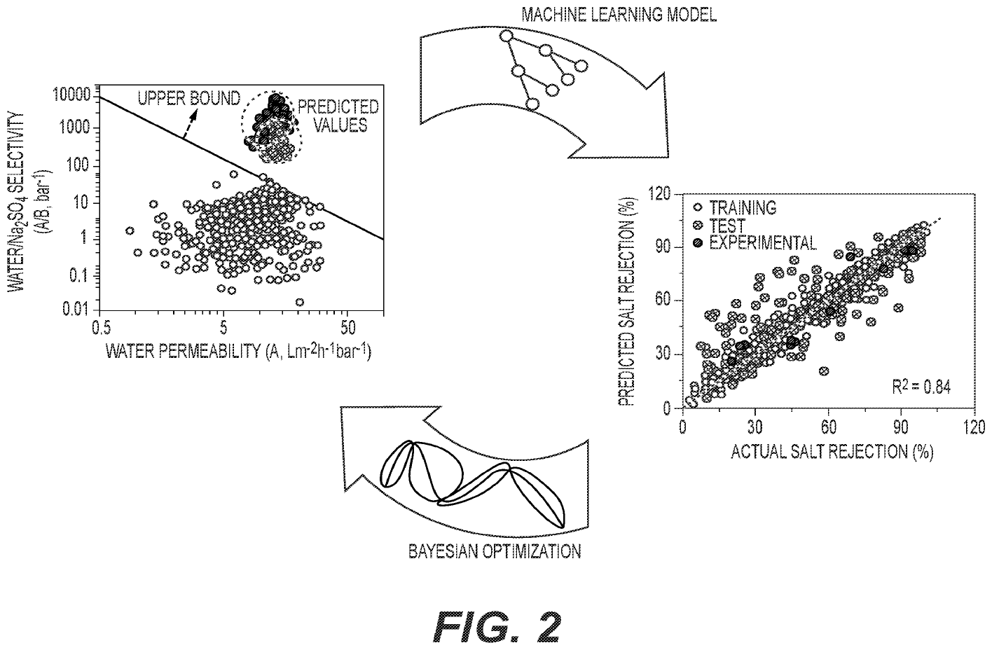

As shown in FIG. 2, the study first developed ML models from literature-based datasets. The study then interpreted the generated model using the Shapley Additive explanation (SHAP) method to select monomer atomic groups with positive contributions toward membrane performance. Further, the study used SHAP-identified beneficial atomic groups to screen new monomers. Next, the study applied Bayesian optimization on the well-developed ML model to inversely identify optimal combinations of monomers and fabrication conditions with the potential to deliver membranes that could break the upper bound of water/salt selectivity and permeability. Finally, the study experimentally validated the performance of fabricated membranes subject to the identified combinations.

Method. Dataset Construction. To construct the datasets, the study mined all of the data for any fabrication conditions that affects PA-based flat-sheet NF membrane performance from 218 reports published between the years 2000 and 2020. The full datasets can be found in [88]. Fabrication conditions included not only numeric features such as monomer concentration, polymerization time, and heat curing time but also categorical features such as additive type, organic solvent, and substrate membrane.

Finally, the study constructed two datasets containing: (1) water permeability (A) and (2) salt rejection (R). The total number of data points for these two datasets varied due to the data availability reported in the literature, with 567 data points for the A dataset and 1524 data points for the R dataset. These two datasets had the same fabrication conditions; the sole difference was in the R dataset, wherein five key properties of salt ions were added: (1) valence, (2) ionic radius, (3) Stokes radius, (4) hydrated radius, and (5) hydration free energy, which was used to differentiate salts (NaCl, Na₂SO₄, MgSO₄, MgCl₂, and CaCl₂)). This treatment enabled a broader collection of data and widened the application of the R dataset for a variety of other salt predictions.

Method. Machine Learning Model Development. One of the key factors determining the successful development of accurate and reliable ML models is how to construct datasets containing missing values in the input features. Missing values refer to the unreported features (i.e., fabrication conditions) in the literature. While missing values were commonly inputted by the mean or median values in previous works [37,46], this study kept them in their raw format (i.e., true missing values) because all of these features have specific physicochemical meanings and affect the membrane performance. The presence of missing values limits the application of certain ML algorithms, such as deep neural network (DNN), making it necessary to employ other ML algorithms, which can process their raw format of missing values. The study utilized two tree-based ML algorithms as candidates: (1) XGBoost (XGBoost Python package) and (2) CatBoost (CatBoost Python package), which are both capable of handling missing values [47, 48]. CatBoost treats missing values for a feature as the minimum or maximum values of that feature, while XGBoost allocates the missing values to the side that reduces the loss in each split. Besides, input features also consist of categorical features (e.g., organic solvent type), which are necessary to be encoded as numeric values prior to developing the MLE model. Eight encoding methods were selected as screening candidates rather than relying on arbitrary selection—BackwardDifferenceEncoder, MEstimateEncoder, SumEncoder, BinaryEncoder, JamesSteinEncoder, OneHotEncoder, BaseNEncoder, and HelmertEncoder [88].

One challenge for developing ML models lies in the functional description of membrane materials (e.g., aqueous phase amine monomers in this work). Common descriptions include molecular fingerprint [38], molecular descriptor [49, 50], molecular image [51], and molecular graph [52].

Molecular images and graphs were not used due to the presence of missing values incompatible with candidate ML algorithms, such as the convolutional neural network for molecular images and graph neural networks for molecular graphs. Here, the study chose the Morgan fingerprint to represent monomers. Compared with other molecular fingerprints (e.g., atom-pair fingerprint), the Morgan fingerprint is more flexible and capable of accurately representing chemical species due to the tunability of atomic group size [53]. The Morgan fingerprint decomposes the chemical structure into several atomic groups to produce a binary vector containing 0's and 1's. The position of the 1's in the vector defines specific atomic groups, which exist in the chemicals.

Atomic group size (i.e., the radius of the Morgan fingerprint) and the number of bits in the vector (i.e., the length of the Morgan fingerprint) are freely tunable, guaranteeing flexibility. With increasing radius, more atomic groups (i.e., those containing 1's in vectors) are included, which increases the possibility of different atomic groups overlapping in the vector. Since the real number of candidate monomers is much larger than the test dataset space, the minimum radius of the Morgan fingerprint was set to 0 to avoid overlapping cases

Meanwhile, the length of the Morgan fingerprint was tuned along with hyperparameters of the ML algorithms. In cases where polymers (such as poly(vinyl amine) and poly(amidoamine)) [54,55] were used for membrane fabrication, the Morgan fingerprint of the repeating unit was applied for this polymer and the polymer's molecular weight (MW) to represent this polymer. When processing polymers using the Morgan fingerprint method, the number of each atom type in a repeating unit and the chemical connectivity between different units of each polymer were read and then decomposed into a binary fingerprint (i.e., vector) as mentioned above. In cases with two monomers, the study combines their Morgan fingerprints.

Method. Model Interpretation. After model development, the study applied the SHAP method to calculate the Shapley value for each feature. The SHAP method works by checking the differences in prediction before and after the feature is removed. Feature-to-feature interaction information is also considered by including all possible ways the feature can be removed. The Shapley value for feature x (out of n total features) given the prediction p by the built ML model was calculated per Equation 1 [56]:

$${∅}_{x} ( p ) = {\sum }_{S ⊆ N / X} \frac{\vert S \vert ! ( n - \vert S \vert - 1 ) !}{n !} ( p ( S ⋃ x ) - p ( S ) ) \qquad ( 1 )$$

In Equation 1, S is the subsets of all features with feature x; p(S∪x) denotes the prediction by the built ML model considering feature x, and p(S) is the prediction without considering feature x. The differences among all possible subsets of S⊆n are calculated due to the dependency of the effect of withholding a feature on other features in the ML model.

The SHAP method was chosen for ML model interpretations and represented a thorough theoretical demonstration of consistent and unbiased interpretation methods for any ML algorithm [57, 58]. A feature's Shapley value quantifies its contribution, whether negative or positive. A feature with a higher absolute Shapley value implies a greater contribution to membrane performance.

Method. Virtual Reference Morgan Fingerprint Construction and Monomer Screening. The SHAP interpretation provided important information regarding atomic groups and their effects on membrane performance. For example, an amine group had a positive Shapley value for water permeability, suggesting that its presence improves water permeability.

Based on this information, monomers containing the carbonyl group are preferred when a high permeability is desired. With this knowledge, the study constructed a reference Morgan fingerprint to record all atomic groups with positive Shapley values (i.e., positive contributions). The reference Morgan fingerprint was used to screen potential monomers. The screening process is to compare similarities between the Morgan fingerprint of each candidate monomer and our constructed reference Morgan fingerprint. Morgan fingerprints of candidate monomers closer to the reference are more likely to contain positive Shapley values, so the study encourages their selection. A Morgan fingerprint similarity between the candidate monomer and the reference is determined by the Tanimoto coefficient (S_{A,B}), which is computed as the number of bits in common divided by the number of total bits per Equation 2 [59]:

$${S}_{A , B} = c / ( a + b - c ) \qquad ( 2 )$$

In Equation 2, a is the number of bits in molecule A, b is the number of bits in molecule B, and c denotes the number of bits that are in both molecules. The Tanimoto coefficient is an intuitive measure of the number of common substructures shared by two molecules. A Tanimoto coefficient of 1 means a completely identical molecule, whereas a value of 0 suggests no similarity between two Morgan fingerprints.

Method. Membrane Fabrication and Performance Evaluation. Two new amine materials (not included in training datasets) (i.e., polyethyleneimine and 1,2-diaminopropane) and one commonly used monomer (i.e., PIP) were used to fabricate PA-based NF membranes by IP to verify ML model predictions on water permeability and salt rejection toward NaCl, Na₂SO₄, MgSO₄, MgCl₂, CaCl₂), LiCl, and NaNO₃. Commercial polyethersulfone microfiltration membranes (PES, MF, 0.2 μm) were chosen as the porous substrates and were immersed in deionized water before use. In brief, a PES substrate was first secured on a glass plate with a funnel and then impregnated with an aqueous monomer solution at a certain concentration for several minutes. The solution was drained, and the excess solution was removed from the substrate surface using a rubber roller. Subsequently, TMC dissolved in anhydrous n-hexane was poured onto the impregnated PES membrane surface for 30 sec. or 60 sec., resulting in the formation of a PA active layer on the substrate. The resultant PA-based NF membrane was rinsed with n-hexane to remove unreacted TMC, then cured at an elevated temperature (60° C.) in an oven to enhance the crosslinking degree of the PA layer. The heat-cured PA-based NF membranes were then stored in water at 4° C. before testing.

Using the same procedure, eight PA-based NF membranes were fabricated according to the optimized fabrication combinations identified by Bayesian optimization.

Water permeability and salt rejection toward different salts for the as-prepared membranes were measured using a crossflow testing cell with an effective testing area of 4.1 cm2 under a crossflow velocity of 0.5 m·s⁻¹. The salt concentration was determined by a conductivity meter (Thermo Scientific). Water permeability (A), salt rejection (R), and water/salt selectivity (A/B) were calculated from Equations 3, 4, and 5.

$$A = \frac{{J}_{w}}{Δ P} \qquad ( 3 )$$

$$R = \frac{{C}_{f} - {C}_{p}}{{C}_{f}} \qquad ( 4 )$$

$$\frac{A}{B} = \frac{R}{( 1 - R ) \times ( Δ P - Δπ )} \qquad ( 5 )$$

In Equations 3-5, J_{w} is the water flux, ΔP is the applied hydraulic pressure, C_{f} and Cₚ are the solute concentrations of the feed and permeate solutions, respectively, B denotes the salt permeability coefficient, and Δπ is the osmotic pressure difference of a specific salt. In this work, the equations for the calculation of A and A/B were simplified by assuming that the concentration polarization coefficient (fcp) is equivalent to 1 [28].

Results. Model Performance. For the development of the ML model, each dataset was randomly divided into a training set (80% of the data points) and a test set (20% of the data points). Numeric features were converted into the same range or distribution through feature scaling. In various possible implementations, it should be considered whether this conversion is necessary, such as for the tree-based ML algorithms used here (XGBoost and CatBoost), and how it may modify predictions of the test set. To screen optimal configuration of ML algorithms, encoding methods and feature scaling methods, five cross-validations were applied to the training datasets to evaluate each configuration. To prevent data leakage, the scaling and encoding methods were only trained on the sub-training dataset rather than the entire training dataset and were then applied to the sub-validation dataset during the cross-validation. The configuration with the best predictive performance was chosen as the final optimal configuration. Under optimal configuration, predictive performance on the training dataset was far superior to that of the validation dataset for both A and R datasets (i.e., overfitting problem). Overfitting was alleviated by tuning the hyperparameters of the corresponding ML algorithms through Bayesian optimization. First, a space containing any possible hyperparameter values was defined. Then, the target loss was set as the average root-mean square error (RMSE) on the validation datasets. The Bayesian optimization algorithms gradually chose a set of optimal hyperparameters, which minimized the loss. The ML algorithms were then retrained on the entire training dataset using optimum hyperparameters to obtain the final models.

The generalization ability of these ML models was evaluated by unseen test datasets, which were not used in model development. As described in Table 1, our trained ML models achieved predictions on the test datasets with a coefficient of determination (R²) value of 0.78 for water permeability. The R² value was improved to 0.84 for salt rejection as the larger size of the R dataset than the A dataset.

TABLE 1
Evaluation of Model Performance

| | training | training | training | test | test | test |
|---|---|---|---|---|---|---|
| objective | size | R² | RMSE^{a} | size | R² | RMSE |
| water | 567 | 0.96 | 1.17 | 141 | 0.78 | 3.01 |
| permeability | | | | | | |
| salt rejection | 1524 | 0.98 | 4.17 | 381 | 0.84 | 11.74 |

^{a}RMSE has the same unit as its corresponding target, that is, water permeability (LMH bar⁻¹) and salt rejection (%) in this work.

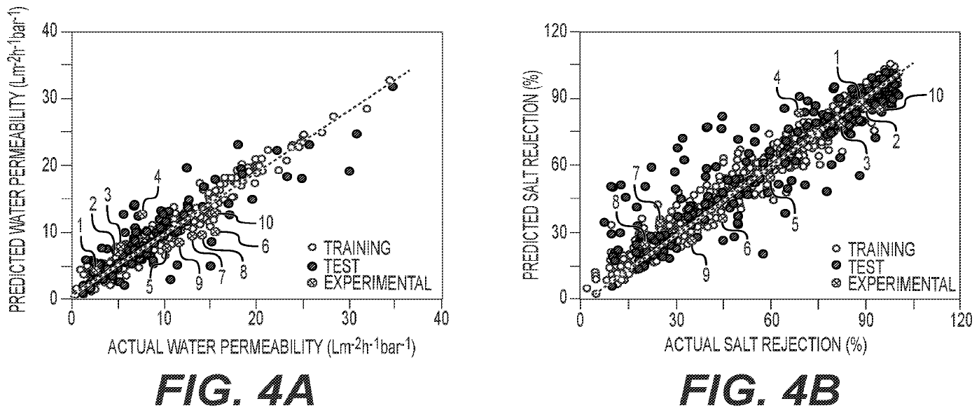

To further evaluate the predictive accuracy of the built models using the test datasets, experimental validation by testing 10 fabricated NF membranes (named from 1 to 10) was performed. In addition to the commonly used monomer, PIP, two other new amine materials, polyethylenimine (PEI, MW1300) and 1,2-diaminopropane (MW 74.125), which were not present in the training datasets, were also used to fabricate PA-based NF membranes. Tests of salt rejection were extended in terms of more diverse salt types (i.e., MgSO₄, MgCl₂, CaCl₂), NaNO₃, and LiCl). Membrane materials used for the fabrication and detailed fabrication conditions are summarized in [88]. It was found that experimental results for both permeability and salt rejection showed relatively good agreement with the predicted values, supporting the reliability of our built models (FIG. 4). Our results suggested that the application of the molecular fingerprint method allowed for the exploration of new monomers not previously studied in the literature. On the other hand, the good agreement on the wide range of salt types tested here proved that it is reasonable to describe salts using the key characteristics of salt ions.

Results. Interpretation of the ML Model. Following validation of the ML model for these two datasets, the model was interpreted to understand the mechanism of prediction from the monomer structures and fabrication conditions. This understanding is essential in the evaluation of ML model predictions while ensuring consistency with fundamental domain knowledge and experimental experience. It also offers insights into desirable atomic groups for improved salt rejection and water permeability.

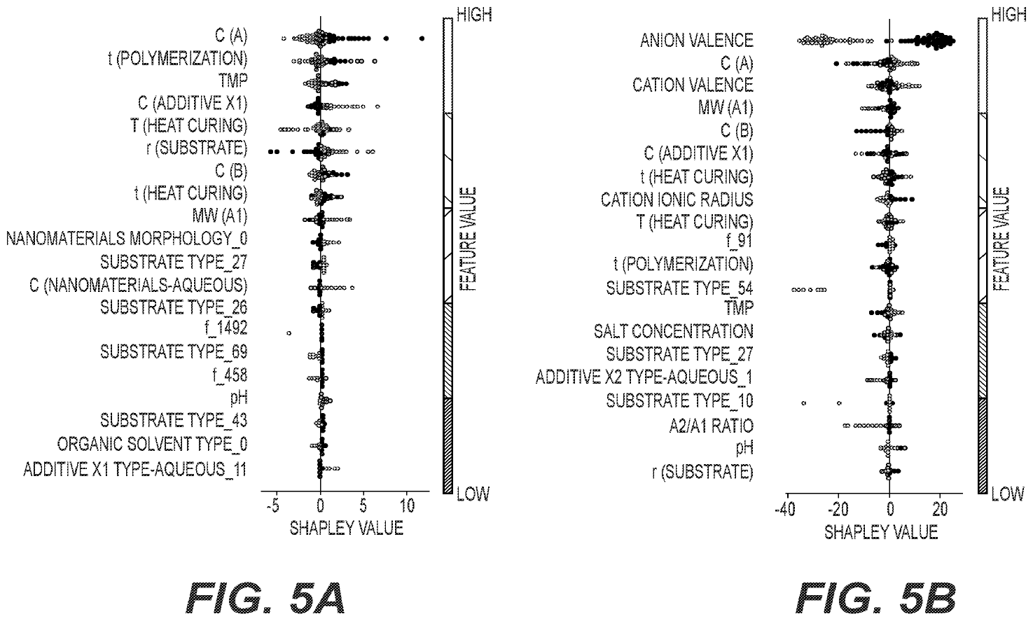

FIG. 5 summarizes Shapley values in terms of water permeability and salt rejection. The most critical contributors for both predicted water permeability and salt rejection were the aqueous-phase monomer concentration (C (A)), aqueous phase additive concentration (C (additive X1)), heat curing temperature (T (heat curing)), organic phase monomer concentration (C (B)), heat curing time (t (heat curing)), and polymerization time (t-(polymerization)). These results agree well with the widely recognized knowledge of PA-based NF membranes fabricated by IP. The performance of PA-based NF membranes depends significantly on membrane properties (e.g., effective membrane thickness, membrane surface charge density, and membrane pore size), as explained by the Donnan-steric pore model with dielectric exclusion (DSPM-DE) [60]. Typically, these properties are tuned by altering fabrication conditions consistent with those identified by Shapley values. From the perspective of positive or negative contributions, a high aqueous-phase monomer concentration forms a thicker PA layer with a greater extent of cross-linking, resulting in reduced water permeability and increased salt rejection. In terms of salt rejection, anion/cation valence plays a crucial role, which is reasonable when considering the mechanisms of ion transport. The transport of charged solutes through NF membranes is largely governed by electrostatic effects, as most PA-NF membranes carry a surface charge [61]. A fixed-charge membrane surface repels co-ions while attracting counterions. The association of Shapley values with underlying NF separation mechanisms enhances the reliability of the built models.

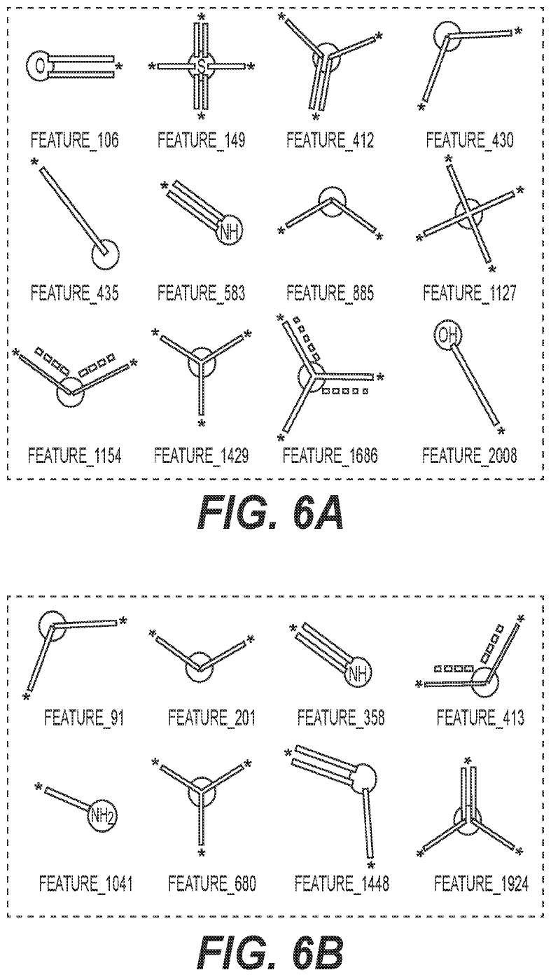

Results. Virtual Reference Morgan Fingerprint and Monomer Selection. Based on the Shapley value of each Morgan fingerprint, all of the atomic groups with positive contributions to the desirable water permeability and salt rejection are demonstrated in FIG. 6. Two reference Morgan fingerprints were constructed by integrating all of them to screen unexplored monomers with the potential to achieve target membrane performance. Thus, 310 candidates of new amine monomers were obtained from the National Institute for Materials Science (NIMS) materials database [62] to screen; these monomers have been synthesized to date, but they have not been experimentally tested in the context of membrane separation. The similarity between the Morgan fingerprint of each new monomer with the two constructed references was then calculated based on equation 2. Accordingly, 20 new monomer candidates with Morgan fingerprint similarities to both reference Morgan fingerprints to execute Bayesian optimization were identified. The 20 monomers were classified into two groups. Group 1 consists of 10 monomers with high Morgan fingerprint similarity. Group 2 is composed of 10 commercially available monomers with lower Morgan fingerprint similarity than that of monomers in Group 1. These monomers contain chemical structures with more positive Shapley value attributes, so it is intuitive that they will exhibit strong performance.

As shown in FIG. 6a, it was found that the atomic groups, feature_106, feature_149, feature_2008, and feature 583, were linked to membrane water permeability. This implies that the presence of hydrophilic functional groups such as carboxyl groups (referring to feature_106), sulfonate groups (referring to feature_149), and hydroxyl groups (referring to feature 2008) largely contributed to water permeability. And the amine groups (referring to feature_583) offered the possibility of getting involved in an interfacial polymerization process. Thus, it was observed that a monomer (i.e., 2,5-diaminopentanoic acid) containing a carboxyl group and an amine group was chosen due to its relatively high similarity to the reference Morgan fingerprint. Similarly, as illustrated in FIG. 6b, amine groups (referring to feature_358 and feature_1041) were found to be beneficial for salt rejection. Monomers consisting of several branched amine groups, such as tris(2-aminoethyl)amine and poly-(ethylenimine) were selected and held the potential to form a highly cross-linked PA network, which is desirable for enhanced salt rejection.

Results. Bayesian Optimization for the Identification of Optimal Combinations and Experimental Validation. Bayesian optimization offers the opportunity to identify a set of optimal combinations of monomers and fabrication conditions that enable the fabrication of membranes with upper-bound breaking performance. To execute Bayesian optimization, firstly, the combination space and initializing reasonable ranges for different fabrication conditions were determined. It is worth noting that the custom objective function (via the loss equation shown below) is calculated from the ML model and is not necessarily continuous over the feasible range of fabrication conditions. This is the reason for adopting Bayesian optimization, which can process discrete objective functions, rather than other large-scale continuous optimization techniques, tackling problems of higher dimensionality but requiring continuity of the objective function [63] per Equation 6.

$$loss = \vert A / B - {y}_{i} \vert + \vert A - {x}_{i} \vert \qquad ( 6 )$$

In Equation 6, A is the water permeability and A/B is the water/salt selectivity. By optimizing the loss equation, multiple combinations of monomers and fabrication conditions can be obtained that can deliver membranes with A and A/B close to (xᵢ, yᵢ), an arbitrarily selected point with a water permeability larger than 10 above the upper bound. By changing this point to any other upper bound-breaking point, the optimizer can provide a series of fabrication conditions delivering membranes with corresponding performance.

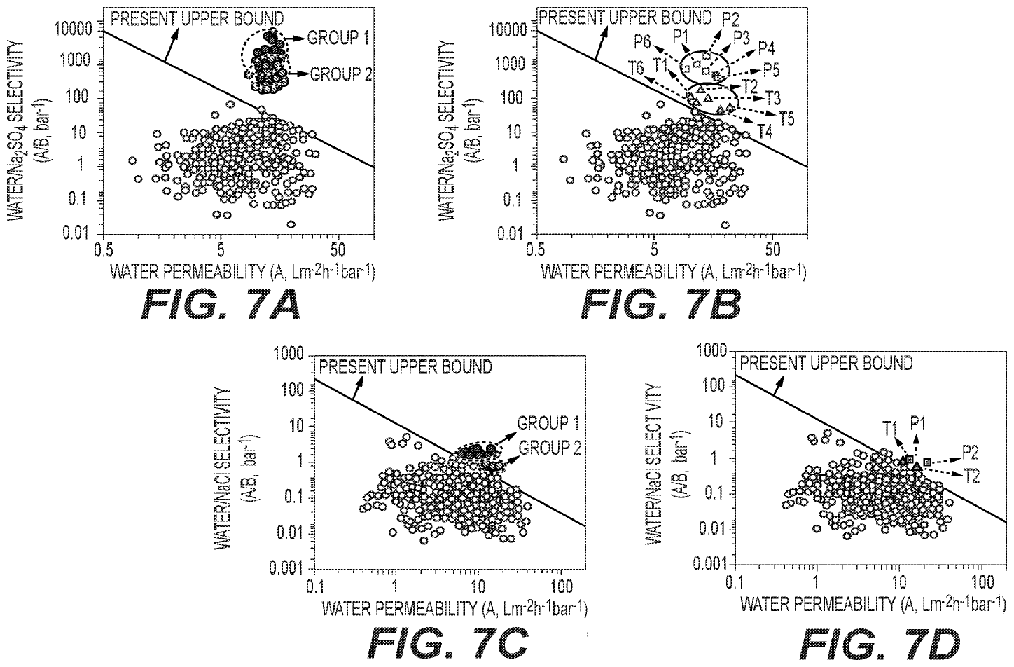

All 20 selected monomers lie significantly above the upper bound of water/Na₂SO₄ selectivity (FIG. 7a,b), although they remain just above the upper bound of water/NaCl selectivity (FIG. 7c,d). Most of the fabrication conditions provided by Bayesian optimization used a mixture of two amine monomers. It has been reported that the cross-linking reaction between amine and acryl chloride might be retarded because of the competing effect between two amine monomers, which could be controlled by the concentration and ratio of the two amine monomers [64]. Under optimal conditions, the relatively less dense PA active layer induced by the retarded cross-linking might offer increased water permeability while maintaining high salt rejection [64-66]. Moreover, for membranes in terms of Na₂SO₄ rejection, sodium dodecyl sulfate (SDS) was used as an additive. The addition of SDS in the aqueous phase has been proved to form uniform pore size distribution with high salt rejection, especially toward multivalent ions [67]. These beneficial conditions synergistically contributed to the upper-bound-breaking performance shown in FIG. 7. However, it is still noteworthy that the target membrane in this work is a polyamide-based NF membrane fabricated through interfacial polymerization. As is well known, the IP process involving the reaction between aromatic amine monomer (such as MPD) and acryl chloride (such as TMC) forms a highly cross-linked polyamide active layer giving NaCl rejection of higher than 90% [68]. The aqueous phase monomers used in this work were semi-aromatic or aliphatic amine monomers less reactive than the aromatic amine monomers, resulting in the formation of a less dense PA layer [69]. Although the combinations of amine monomer and fabrication conditions could be significantly optimized using Bayesian optimization, the obtained membranes were still in the NF membrane region with NaCl rejection <90%. In this work, when executing Bayesian optimization, the water permeability was targeted at 10 LMH bar⁻¹ or higher, which is higher than what could be achieved by membranes in the RO region [28]. Under such conditions, the overall permeability-NaCl selectivity of the membranes provided by the Bayesian optimization was limited to reside just above the upper bound.

To validate the identified combinations, eight PA-based NF membranes with new monomers from group 2, according to the top—10 identified combinations—were fabricated. The water permeability of these membranes and their salt rejection in terms of NaCl and Na₂SO₄ were tested to verify the optimization results. Experimental results were transformed to the corresponding water/salt selectivity and plotted with their predicted values (as shown in FIG. 7). For both NaCl and Na₂SO₄, discrepancies between experimental data and predicted values were observed. Bayesian optimization was performed based on the built ML models, which were developed using literature-based data for polyamide NF membranes fabricated interfacial polymerization. For training ML models, a wide range of input features (i.e., fabrication conditions), such as monomer concentration, polymerization time, organic type, additives, nanomaterials, etc., were included. However, the candidate fabrication conditions used for Bayesian optimization were restricted to a smaller space than those in the training dataset. The focus of the optimization was on influential conditions to both water permeability and salt rejection, as highlighted by the Shapley values (as shown in FIG. 5), referring to the concentration of aqueous phase monomer (C(A)), the concentration of additive concentration (C(additive X1)), the concentration of organic phase monomer (C(B)), polymerization time (t), heat curing time, and temperature. Therefore, the model may show a weaker predictive performance in this smaller space. In addition, when developing ML models, concentration polarization was not included as an input feature. However, the influence of concentration polarization on salt rejection might be another reason for the discrepancy.

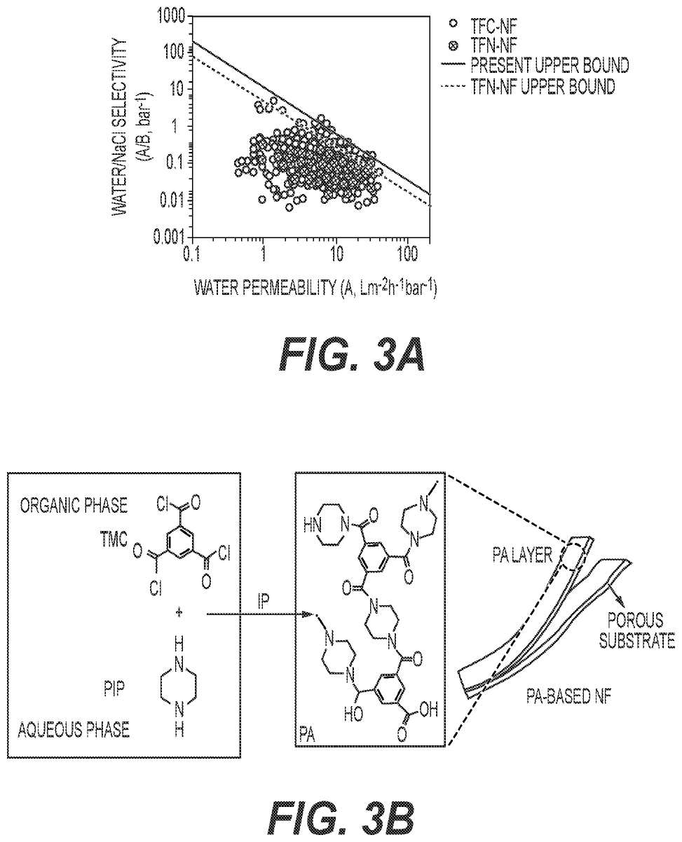

As revealed by the Shapley values in FIG. 5, the incorporated nanomaterials also made positive contributions to improve water permeability. Thus, the candidate input features used in the Bayesian optimization were extended to include the nanomaterial type in an aqueous phase, the loading of nanomaterial used, and nanomaterial morphology in addition to the most influential fabrication conditions mentioned above. Cellulose nanocrystal (CNC) was selected as the nanomaterial used to fabricate NF membranes. Based on the monomers and fabrication conditions provided by Bayesian optimization, two TFN membranes were fabricated. As shown in FIG. 7b, overall, the TFN membranes referring to membranes 5 and 6 did not show excellent performance compared to the TFC membranes referring to membranes 1-4. According to the Shapley values, although the addition of nanomaterials played a role in enhancing water permeability, the contributions of nanomaterials to salt rejection were not as important as other fabrication conditions (e.g., monomer concentrations, polymerization time, etc.), which might lead to the fair permeability-selectivity performance of TFN membranes. On the other hand, differing from the monomers, which could be new ones selected from a large material database, the selection of nanomaterials for the Bayesian optimization was limited to those collected in the constructed datasets (as found in the Supporting Data). The addition of nanomaterials selected from the datasets such as the CNC used here did not always guarantee better performance than membranes without nanomaterials, which aligned with the statistical trend shown in FIG. 3.

Results. Implications of ML-Based Bayesian Optimization Strategy. The ML model-based Bayesian optimization demonstrated here is an effective and efficient strategy to inversely supervise membrane design, which is free of the standard current trial-and-error approach. Rapid screening of unexplored materials can be accomplished with the ML model-based Bayesian optimization by constructing a reference Morgan fingerprint based on the chosen atomic groups derived from ML model interpretation. Hereafter, Bayesian optimization on the well-developed ML model is a useful and innovative tool to explore numerous space possibilities for more efficient membrane design. By identifying the optimal combinations of membrane materials and fabrication conditions, Bayesian optimization allows one to fabricate PA-based NF membranes with upper-bound-breaking performance. These NF membranes can be utilized for efficient water purification and water softening, especially for multivalent ions removal. These membranes are supposed to have the potential to achieve high emerging contaminants removal since the size of some contaminants (such as antibiotics, sulfamethoxazole) is larger than SO₄²⁻. Research interest is increasing in emerging applications of polymeric separation membranes (e.g., solute-solute selectivity from multicomponent systems, emerging contaminants removal, and recovering nutrients and valuable metals from wastewater waters). It is contemplated that efficient solute-solute selectivity may be best screened from optimization combinations trained on a broader range of data, which may include multicomponent or mixed-salt (e.g., the presence of salts and emerging contaminants) systems. Additionally contemplated is the use of the built ML model applied to hollow fiber membranes, using relevant hollow fiber membrane data for training the ML model and optimization. Because the prediction performance of the ML models strongly depends on the availability, accuracy, and size of a dataset, with more studies related to these applications being published, the strategy demonstrated in this contribution can be easily extended to develop appropriate models and guide in designing different types of membranes for those emerging applications.

### Example: High-Performance Ultrafiltration Membrane

In this work, tree-based ML models were developed using extreme gradient boosting (XGBoost) and categorical boosting (CatBoost) as potential candidates to analyze a data set containing input features associated with both fabrication and operational conditions and to target membrane performance. As for membrane performance, water permeability, removal efficiency, and indices associated with membrane antifouling performance, such as the flux decline ratio, flux recovery ratio, and reversible fouling ratio, were considered. The relative importance and impact of each feature on the target were evaluated using the Shapley additive explanations (SHAP) method to provide guidance on fabricating (ultrafiltration) UF membranes with desirable water permeability, removal efficiency, and antifouling potential. Moreover, predictive ML models were also developed by correlating fabrication conditions with membrane properties and carried out model interpretations with the SHAP method. This interpretation facilitated a better understanding of the underlying mechanics in terms of the influence and contribution of each fabrication parameter to membrane performance. This work demonstrated the potential of ML methods in providing guidance to fit-for-purpose membrane development to meet challenges in water and wastewater treatment and resource recovery.

Method. Data collection and data set construction. The quantity and quality of collected data used to develop ML models were crucial to the model prediction performance. To develop ML models with accurate prediction, data from research articles associated with flat-sheet polymeric UF membranes fabricated by the most used non-solvent-induced phase separation (NIPS) method at room temperature were mined to construct the data sets with a total size of 320. Parameters and descriptors used as input features were exhaustively collected from tables, text, and graphical data. On the basis of empirical domain knowledge, these input features were assembled into three categories consisting of fabrication conditions (11 variables), operational conditions (six variables), and membrane properties (four variables). The ratio between variables and total data size was calculated to be 6.6%. Features describing the fabrication and operational conditions involved both numerical parameters such as polymer concentration (P_wt %), pore maker content (M_wt %), and the loading of the additives (A_wt %) and categorical ones such as the types of pore makers and organic solvents. In the constructed data sets, the additives were specifically referenced to various types of nanomaterials. The categorical features were first converted into numeric ones by the encoding methods. Eight encoding methods were screened, and the optimum one to convert these categorical features into numeric features was selected-BackwardDifferenceEncoder, MVEstimateEncoder, SumEncoder, BinaryEncoder, JamesSteinEncoder, OneHotEncoder, BaseNEncoder, and HelmertEncoder [89]. Notably, features with insufficient information, such as the absence of molecular weights for polymers and pore makers, were designated as missing values rather than being excluded. The base polymers were represented by molecular fingerprints encoding the repeating unit as a binary vector (0, 1) by converting its SILES in Python's RDKit package. The obtained molecular fingerprints of the polymers combined with other numerical features (including those from converted categorical features) were used as the final input features to develop MIL models. Generally, three data sets were compiled, one for the prediction of membrane performance from fabrication and operational conditions, one for the prediction of membrane performance with the combination of fabrication/operational conditions and membrane properties as input, and the third for the prediction of membrane properties from fabrication conditions.

Method. Machine Learning Model Development and Evaluation. As all of the features have their specific physicochemical meanings, the missing values present in the input features were not imputed. Hence, it is necessary to employ ML algorithms with the capability of processing missing values. Tree-based algorithms have been reported to exhibit satisfactory performance in handling missing values containing data sets. Here, two tree-based ML algorithms, i.e., XGBoost and CatBoost, were analyzed as candidates. The tree-based IL model for each data set was developed in a similar manner with some modifications depending on the specific data set. The data set was randomly split into two parts: 80% of the whole data set as the training set and the remaining 20% of the data set as the test set for model evaluation. Fivefold cross-validation was employed on the training set to screen the IL algorithms, encoding methods, and hyperparameter tuning. After the optimum configuration of MIL algorithms and/or encoding methods had been screened, the hyperparameters of the MIL. algorithm were then tuned by using the Bayesian optimization algorithm. The length and radius of the molecular fingerprint were considered as hyperparameters, which were tuned together with other hyperparameters of ML algorithms. After obtaining the optimum hyperparameters, the ML algorithm was retrained with the optimal hyperparameters on the whole training set (without using 5-fold cross-validation) to deliver the final ML models. The predictive performance (i.e., generalization ability) of ML models was evaluated on the test set. The coefficient of determination (R²) and root-mean-square error (RMSE) were utilized to evaluate the prediction accuracy as defined below. The lower RMSE and higher R² indicate the better predictive performance of ML models.

$${R}^{2} = 1 - \frac{{\sum }_{i = 1}^{n} {( {x}_{p}^{i} - {x}_{t}^{i} )}^{2}}{{\sum }_{i = 1}^{n} {( {x}_{t}^{i} - {x}_{m} )}^{2}} \qquad ( 7 )$$

$$RMSE = \sqrt{\frac{{\sum }_{i = 1}^{n} {( {x}_{t}^{i} - {x}_{p}^{i} )}^{2}}{n}} \qquad ( 8 )$$

In Equations 7 and 8, xₚⁱ is the predicted value of the output, xₜⁱ is the actual value of the output reported in the literature, xₘ is the mean value of all of the output, and n was the number of data points in the training or test set.

Method. Feature Analysis. To understand the built models and thus provide insightful guidance for future membrane fabrication, identifying potential controlling fabrication parameters for membrane properties and performance was essential. In previous work, feature importance analysis had been performed to explain different models (such as random forest and neural network), providing insight into the roles of input features [73, 75]. Here, the importance and impact of each feature on the targets were analyzed using the SHAP method [72]. The Shapley value for input feature x (of n total input features) given the prediction p by the built ML model was calculated per equation 1 [76].

Method. Characterization of Membrane Properties. To further validate the model prediction accuracy, three UF membranes were fabricated using NIPS methods. The water contact angle (CA) indicating membrane surface hydrophilicity was measured by a Ramé-Hart model 250 goniometer (Rame-Hart Instrument Co.). The average membrane pore radius (micrometers) was determined on the basis of the Guerout-Elford-Ferry equation [77] per Equation 9.

$${r}_{m} = \sqrt{\frac{( 2.9 - 1.75 ε ) \times 8 η lQ}{ε A Δ P}} \qquad ( 9 )$$

In Equation 9, η is the water viscosity at 23° C. (9.3×10⁻⁴ Pa s), Q is the permeate flow rate (cubic meters per second), and ΔP is the operational pressure (pascals). The overall porosity (percent) of a membrane was measured by the dry-wet weight gravimetric method as expressed by Equation 10.

$$ε = \frac{{w}_{w} - {w}_{d}}{Al ρ} \qquad ( 10 )$$

In Equation 10, w_{w} is the weight of the hydrated membrane (grams), w_{d} is the weight of the dried membrane (grams), A is the surface area of the membrane (square centimeters), l is the membrane thickness (centimeters) determined by the cross-section SEM image, and ρ is the water density at 23° C. (0.998 g cm⁻³).

Method. Evaluation of Membrane Performance. The pure water permeability of the fabricated membranes was measured using a dead-end ultrafiltration cell (Amicon stirred cell, Millipore Sigma) with an effective membrane area of 13.4 cm². The membranes were precompacted under 4 bar for 2 h before switching to the operating pressure of 1-1.5 bar. Bovine serum albumin (BSA) solution was used as the feed solution to test the rejection performance of the membranes. The concentration changes of BSA were determined using a Shimadzu TOC-L analyzer (Shimadzu Scientific Instruments). The water permeability (A) and rejection efficiency (r) were calculated per Equations 3 and 11:

$$R = \frac{{C}_{0} - {C}_{t}}{{C}_{0}} \times 100 \% \qquad ( 11 )$$

In Equation 11, C₀ and Cₜ refer to the concentrations of BSA in the feed solution and permeate, respectively.

Membrane fouling performance was evaluated using humic acid (HA) as the model foulant. The membranes under investigation were first compacted for 2 h under applied hydraulic pressure to reach a steady water flux. The water flux was recorded for an additional 1 h to obtain the pure water flux (J_{w}). Subsequently, the pure water was converted into the HA solution and allowed to run for 6 h at the same applied hydraulic pressure. The steady flux with a 20 mg L⁻¹ HA solution as the feed was recorded as Jₜ. Then, the fouled membrane was physically cleaned with deionized (DI) water. After physical cleaning, the recovered pure water flux (Jᵣ) was recorded for an additional 1 h with DI water as the feed solution. The flux decline ratio (FDR) coupled with the water flux recovery ratio (FRR) was used to evaluate the membrane antifouling potential based on equations 8 and 9 [78]. Generally, the lower FDR and the higher FRR suggest a better antifouling performance of the membranes per Equations 12 and 13.

$$FDR = ( 1 - \frac{{J}_{t}}{{J}_{w}} ) \times 100 \% \qquad ( 12 )$$

$$FRR = \frac{{J}_{r}}{{J}_{w}} \times 100 \% \qquad ( 13 )$$

Membrane fouling can be generally classified as reversible and irreversible fouling. The flux decline ratio caused by reversible and irreversible fouling during the filtration process was calculated per Equations 14 and 15.

$${R}_{r} = \frac{{J}_{r} - {J}_{t}}{{J}_{w}} \times 100 \% \qquad ( 14 )$$

$${R}_{ir} = \frac{{J}_{w} - {J}_{r}}{{J}_{w}} \times 100 \% \qquad ( 15 )$$

Results. Predictive ML Models. To simplify the ML model and enhance its performance, the Pearson correlation coefficient (PCC) was determined to identify the correlations between features. With respect to membrane performance, the irreversible fouling ratio showed a completely negative correlation with the flux recovery ratio (i.e., PCC=−1), which is in line with the calculation result according to equations 9 and 11. Therefore, the irreversible fouling ratio was sorted out from the output target and the flux recovery ratio was chosen as the representative one.

Overfitting was controlled by tuning the hyperparameters of the machine learning algorithm to control the complexity of the model. The Bayesian optimization algorithm was used to tune the hyperparameters of the machine learning algorithm, in which the training and validation performance together was observed. The hyperparameters that can afford the best validation performance were used as the optimum hyperparameters.

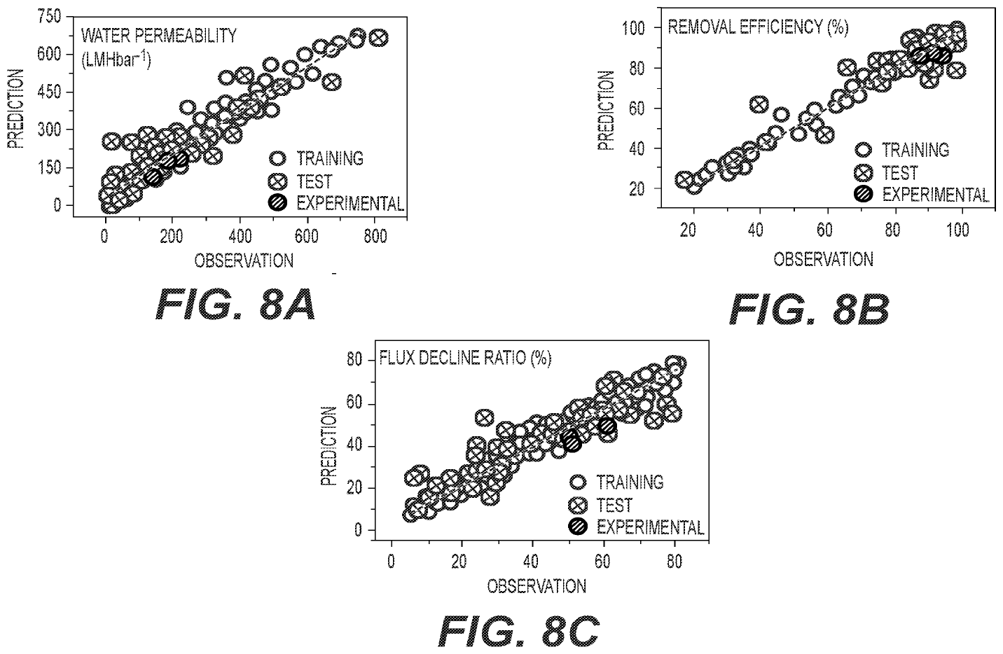

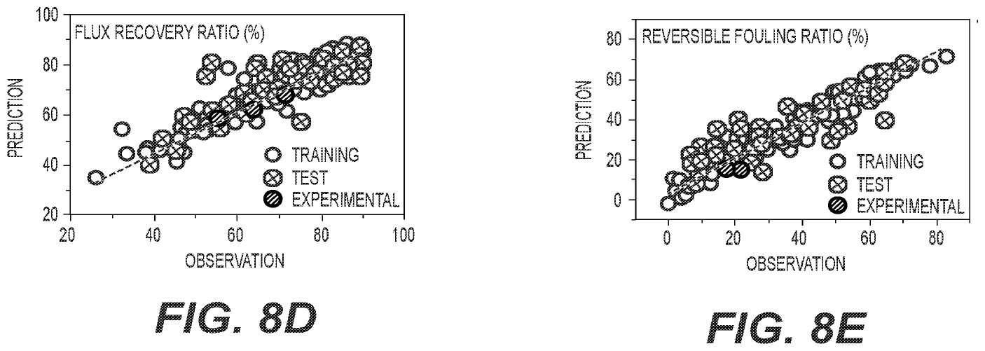

The predictive performance of the built ML model for each target is listed in Table 1 and plotted in FIG. 8. The prediction of ML models in the test data sets exhibited an R² value of 0.78 for water permeability, removal efficiency, and flux decline ratio. These results indicated the strong quantitative correlation of membrane performance with the fabrication conditions and operational conditions. In comparison with the prediction performance of these three targets, the models exhibited relatively lower testing R² values of 0.62 and 0.73 for the flux recovery ratio and reversible fouling ratio, respectively. As expressed in equations 9 and 10, these two targets were highly relevant to the recovered water flux after physical cleaning. Therefore, the relatively limited prediction performance for the flux recovery ratio and reversible fouling ratio may be attributable to the case-by-case variations in the physical cleaning procedures. Improvements in the prediction performance could be achieved by expanding the current data sets to include more reasonable variables as input features, such as the cleaning time of the physical cleaning process.

As membrane performance mainly depends on membrane properties, ML models were developed for predicting membrane performance by including membrane properties (e.g., mean pore radius, overall porosity, contact angle, and surface roughness) together with fabrication/operational conditions as input features. The prediction of the ML models with membrane properties exhibited an R² value comparable to those of the ML models without membrane properties. These results revealed the quantitative relationship among fabrication, property, and performance.

To further validate the generalization ability of the developed ML models, three UF membranes were fabricated and tested their performance. Our experimental data points were independent of the 320 data points collected from the literature. The experimental results for all of the targets showed relatively good agreement with the predicted values (FIG. 8). This finding indicated that all of the built ML models were reliable enough to provide satisfactory predictions of membrane performance based on the selected input features. Notably, the polymers used to fabricate these three membranes have molecular weights different from those of the polymers enclosed in the collected data sets. The application of the molecular fingerprint method made it possible to deliver acceptable performance predictions for membranes fabricated with new polymers. However, the additive as a categorical feature was encoded to the numerical feature in this work, which limited the prediction capability of the built model for cases with new additives (i.e., those not present in the training data set).

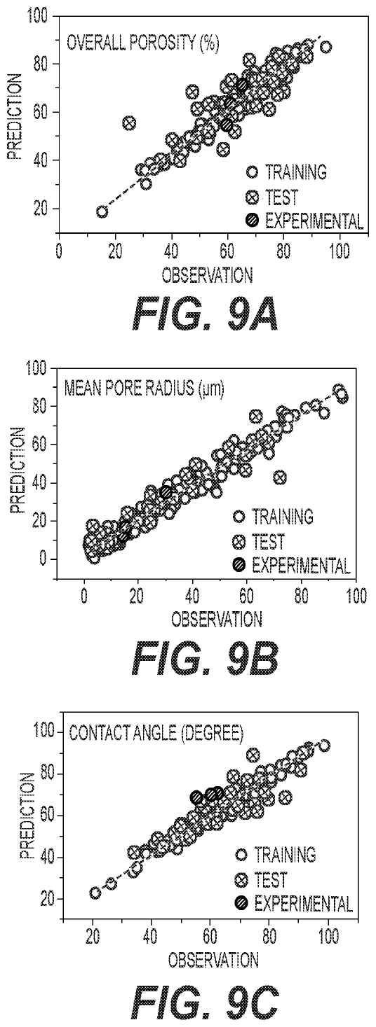

To understand the correlation between membrane properties and fabrication conditions, ML models were developed to predict three major membrane performance-determining properties, i.e., mean pore radius, overall porosity, and contact angle (revealing the hydrophilicity of the membrane surface), using fabrication conditions as input features. As shown in Table 2, for the test data sets, the R² values were 0.87 and 0.76 on the prediction of mean pore radius and contact angle, respectively, and their corresponding RMSEs were 7.59 and 5.87, respectively, suggesting satisfactory prediction performance of the built ML models with fabrication conditions as input features. In comparison with the prediction performance on mean pore radius and contact angle, the R² value of 0.66 for overall porosity was relatively lower, which could be partially explained by the variations in data quality due to the dry-wet gravimetric measurement method as calculated in equation 6. Notably, the observed membrane properties of the fabricated membranes were in line with the predicted values, as indicated by the blue dots in FIG. 9. This experimental validation further confirmed the prediction accuracy of the three predictive ML models on membrane properties.

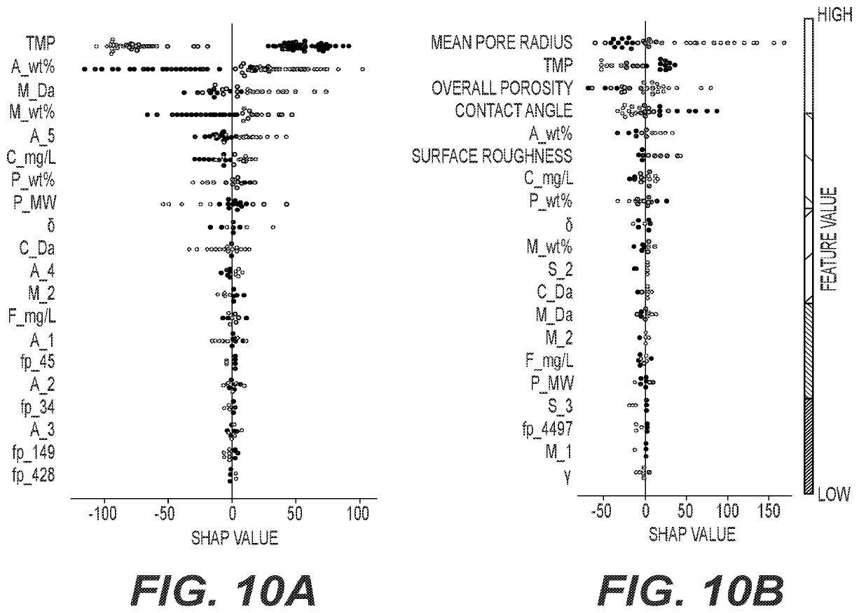

Results. Feature analysis using SHAP Method. According to the built M L models, the contributions of each input feature to the targets (i.e., membrane performance) were evaluated using the SHAP method. A feature's Shapley value quantifies its contribution, whether negative or positive. A feature with a higher absolute Shapley value implies a greater contribution to membrane performance. FIG. 10a illustrates the importance and impact of each feature on membrane performance. In general, the loading of additives (A_wt %), the polymer content of the total casting solution (P_wt %), the molecular weight of the pore maker (M_Da), and the pore maker content (M_wt %) were found to be the four most influential fabrication parameters for predicting membrane performance. Notably, A_wt % was found to be the most important fabrication parameter for predicting membrane performance indices except for the flux decline ratio, for which A_wt % ranked second in importance. With respect to water permeability, as shown in FIG. 10a, it is noteworthy that the feature A_5 also played an important role in improving water permeability. As described in the data collection and data set construction section, the category features were first converted into numerical features. Here, A_number stands for the encoder of the category feature (i.e., the type of additive). The SHAP plot demonstrated that A_5 positively contributed to water permeability, which means that the additive having an A_5 value of 1 (such as UiO-66) might be a desirable additive for enhancing water permeability. Because the additive was identified as a significant contributor to membrane performance, to optimize the robustness of the ML models and gain more insights into the effects of the additive, future work may focus on compiling data sets with structural parameters of the additives, especially nanomaterials (such as size, length, shape, and diameter) as well as its chemical properties (e.g., (potential, hydrophilicity, and surface functional groups).

Additionally, the operational conditions played considerably important roles in membrane performance. In particular, the transmembrane pressure (TMP) was integral to water permeation, while the molecular weight of contaminants (C_Da), concentration of contaminants (C_mg/L), and concentration of foulants (F_mg/L) played crucial roles in removal efficiency- and membrane fouling-related performance. As demonstrated in FIG. 10a, TMP was negatively correlated with water permeation. Such a negative effect of applied hydraulic pressure on water flux was mainly ascribed to the compaction of the polymeric membrane [79, 80]. The compaction under different applied pressures resulted in a reduction in the membrane pore size and porosity, which agreed well with the contribution of pore size and porosity to water permeability (FIG. 10b). C_Da was positively correlated with removal efficiency. The separation of UF membranes was dictated by the molecular-sieving mechanism indicated by the molecular weight cutoff (MWCO), where the large solutes were retained by the smaller pores to achieve high removal efficiency [81]. These findings verified the necessity of developing an ML model with operational conditions included (in addition to the fabrication parameters) as input features.

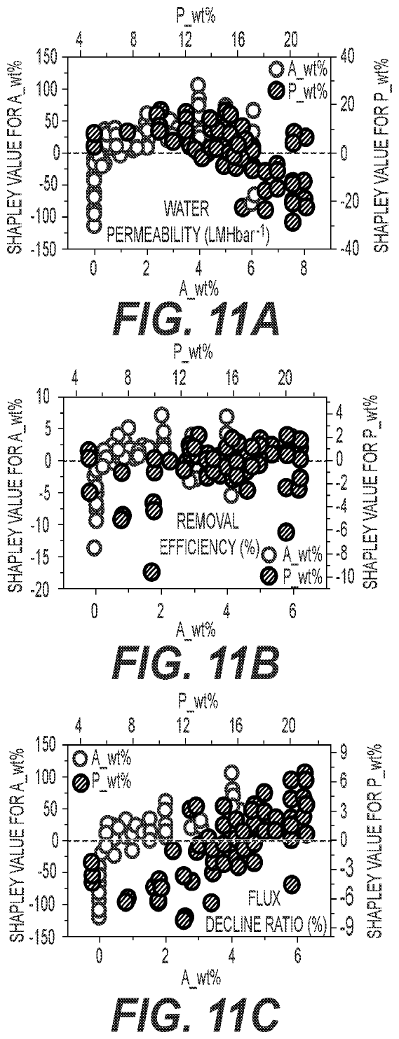

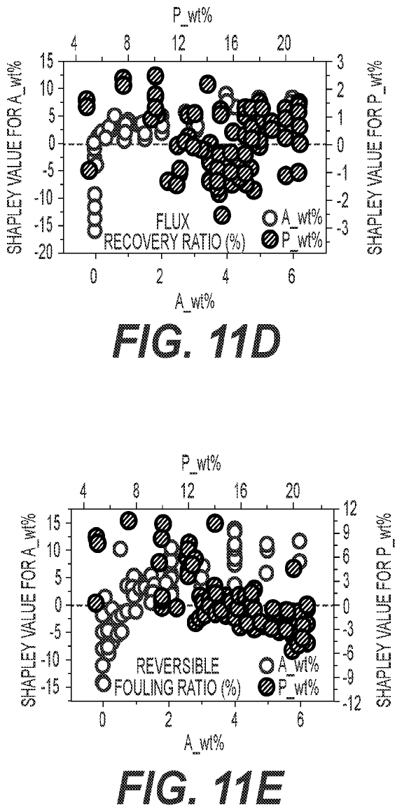

As shown in FIG. 11, A_wt % was positively correlated with water permeability, removal efficiency, and flux recovery ratio with a loading of >0.5 wt % (defined by the weight percentage of an additive to the base polymer), while the beneficial loading for the flux decline ratio and reversible fouling ratio was found to be >1.0 wt % (FIG. 11c,e). These findings revealed that incorporating 1.0 wt % additives (specifically nanomaterials) into a polymer matrix could potentially afford a membrane with high water permeability and removal efficiency, as well as antifouling performance. As the backbone of a membrane, the polymer used to fabricate the UF membrane was expected to be a crucial feature. As shown in FIG. 11, P_wt % had a significant impact on membrane performance, especially on water permeability. With P_wt % ranging from 10 to 16 wt %, it was positively correlated with water permeability. Beyond 16 wt %, a strongly negative correlation with water permeability was observed. It might be attributed to the delayed phase inversion due to the higher polymer content, which normally resulted in less porosity and a small pore sizes in the membrane [82]. This trend was in accordance with the results shown in FIG. 10b, wherein the pore size and porosity exhibited a positive correlation with water permeability. Notably, as for removal efficiency, flux recovery ratio, and reversible fouling ratio, the Shapley value of P_wt % was comparable to that of A_wt %, while in terms of water permeability and flux decline ratio, the Shapley value of A_wt % was much larger than that of P_wt %, suggesting that in comparison with tuning the polymer content, tailoring the additional loading of nanomaterials into the polymer matrix might be a more effective method for achieving a UF membrane with desirable membrane performance, especially enhanced water permeability and a decreased flux decline ratio. In practical water and wastewater treatment applications, UF membranes with a lower flux decline ratio are desired as it indicates that such a membrane holds better antifouling potential.

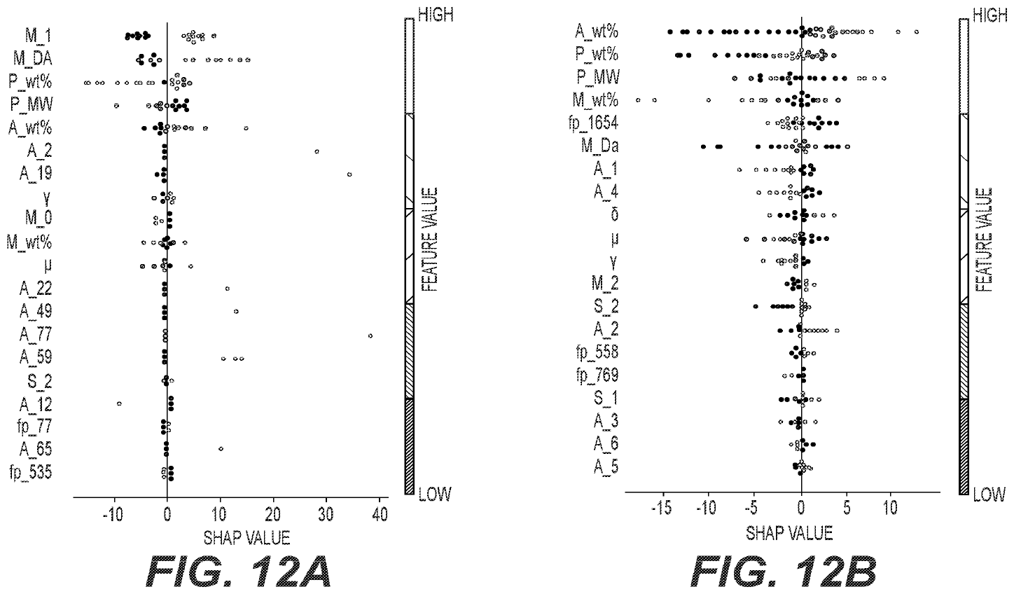

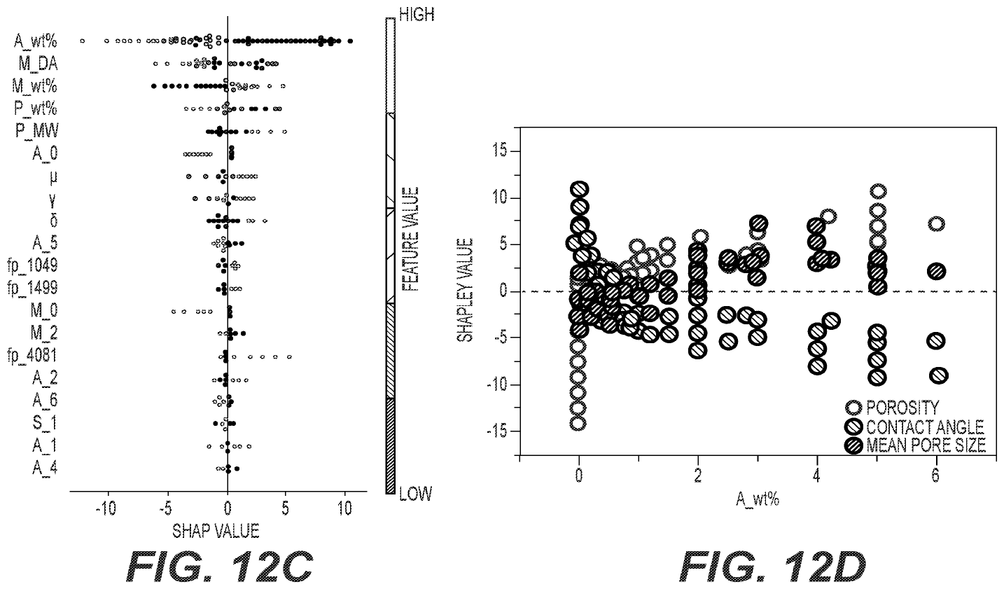

FIG. 12 displays the feature analysis of the ML models for the prediction of membrane properties. The ranking of the features' importance for predicting membrane properties was in accordance with that for membrane performance prediction. In the analogue to the prediction of membrane performance, A_wt %, P_wt %, M_Da, and M_wt % were also found to be the four most significant fabrication factors dominating membrane property prediction. Therefore, the influence of these factors on membrane performance prediction can be explained by their contributions to each of the membrane properties. A_wt % was positively correlated with the mean pore size and overall porosity and negatively correlated with the contact angle at a loading of >1.0 wt % (FIG. 12d), which was highly consistent with the beneficial range of A_wt % for membrane performance. This revealed that an increased addition of additives (referring to nanomaterials in the collected data sets) contributed to the formation of a larger pore size, a higher porosity, and a smaller contact angle indicating higher surface hydrophilicity [83,84], typically leading to desirable water permeability [85,86], which agreed well with the results shown in FIG. 10b.

It has been reported that irreversible fouling rapidly occurred as a result of internal pore blockage, followed by the formation of a cake layer on the membrane surface [87]. The pore constriction-induced irreversible fouling resulted in the progressive decline of the membrane water flux. Therefore, a smaller pore might make it difficult for foulants to enter and constrict the pores, which in turn could afford a lower flux decline ratio. The mean pore radius positively correlated with the flux decline ratio, revealing that a smaller mean pore radius contributed to a lower flux decline ratio, which was a desirable performance for separation membranes. P_wt %, A_wt %, P_MW, and M_Da were found to be the four most influential factors in predicting the flux decline ratio. A possible reason could be these four factors showed significant effects on the mean pore size of the membrane as illustrated in FIG. 12a. The flux recovery ratio and reversible fouling ratio, which could be promoted through hydraulic cleaning, largely depended on the membrane surface hydrophilicity inferred from the contact angle. The ranking of features for the flux recovery ratio and the reversible fouling ratio indicated that the contact angle was the most important property for both performance indices. The four most important factors governing the prediction of the flux recovery ratio and the reversible fouling ratio were identified as A_wt %, P_wt %, M_Da, and M_wt %, which was consistent with the top four factors contributing to the contact angle.

The ML algorithm and the subsequent Bayesian optimization mainly focus on testing and optimization of commercially available monomers. Most monomers are derived from petroleum-based raw materials, which, upon disposal, contribute to the omnipresent issue of inert plastic waste. The developed method can facilitate researchers to map the chemistries and structures of unexplored membrane materials, enabling the identification and selection of high-performance, environmentally friendly, sustainable membrane materials derived from bio-based raw materials. More importantly, the present description provides a data-driven computational framework for the development of membranes and will be useful across the membrane field, which could potentially make a massive difference in how fast membranes are tailored for one or another application. By extension, this strategy could also serve as a roadmap for the development of materials for environmental remediation in other technologies (e.g., adsorbers, catalysts, etc.).

### Discussion

Water scarcity is one of the most critical global challenges. Membrane separation offers the best options to “drought proof” mankind on an increasingly thirsty planet through harvesting clean and safe water from unconventional water resources (e.g., seawater, brackish water, and wastewater) in a sustainable manner [1].

Membrane technology is based on a range of synthetic membranes with various functions made from polymers or inorganic materials or mixtures thereof. To date, synthetic membranes including microfiltration (MF), ultrafiltration (UF), nanofiltration (NF), and reverse osmosis (RO)) have been developed for water/wastewater treatment. Of these, MF and UF have become major technologies for water treatment from non-saline sources, pretreatment for RO processes in wastewater treatment and in membrane bioreactors [1]. With the development of thin-film composite polyamide (TFC-PA) membranes, freshwater can now be efficiently produced through NF and RO from saline water (e.g., seawater and brackish water) desalination and wastewater reuse [2]. One important parameter for evaluating membrane separation performance is membrane selectivity, quantifying the extent to which the targeted solutes are separated from the other solutes of aqueous solutions [3]. While membrane desalination requires separating all solutes from feed water, precise solute separation refers to the separation of solutes from each other, that is, having a very high rejection for some species and a very low rejection for the others [4]. Designing performance-targeted separation membranes with “fit-for-purpose” selectivity can be of paramount importance.

Membrane fabrication is a complex and multidimensional process involving selection of membrane materials and optimization of fabrication conditions from an infinite candidate space. Current membrane development is still relying on exhaustive experimental investigations by conventional screening procedures, which results in heavy development cost and time. In addition, over the past few decades, advances in the development of polymer-based membrane materials have been limited, greatly relying on empirical approaches [2]. Switching the conventional trial and error fabrication process (e.g., exploring new membrane materials with optimal properties and searching for numerous combinations of materials, fabrication conditions and operational settings) to a more efficient and non-trial-based membrane design strategy remains an open challenge. As the core technique in the new paradigm of scientific cognition, machine learning, powered by rapidly growing computational resources, has remarkably accelerated the speed of new materials' discovery due to its robust ability to mine intrinsic correlations by autonomous learning and solving highly dimensional, large-scale optimization [5,6]. Recent studies have applied data-driven models such as artificial neural network (ANN) and tree-based ML models for designing thin film nanocomposite (TFN) membranes and predicting TFC-PA membrane performance in reverse osmosis (RO), NF and organic solvent nanofiltration [7-13].

### Artificial Intelligence and Machine Learning

In addition to the machine learning techniques described above, the various aspects of the data-driven modeling may be implemented using other artificial intelligence and machine learning techniques.

The term “artificial intelligence” is defined herein to include any technique that enables one or more computing devices or comping systems (i.e., a machine) to mimic human intelligence. Artificial intelligence (AI) includes, but is not limited to, knowledge bases, machine learning, representation learning, and deep learning. The term “machine learning” is defined herein to be a subset of AI that enables a machine to acquire knowledge by extracting patterns from raw data. Machine learning techniques include, but are not limited to, logistic regression, support vector machines (SVMs), decision trees, Naïve Bayes classifiers, and artificial neural networks. The term “representation learning” is defined herein to be a subset of machine learning that enables a machine to automatically discover representations needed for feature detection, prediction, or classification from raw data. Representation learning techniques include, but are not limited to, autoencoders. The term “deep learning” is defined herein to be a subset of machine learning that that enables a machine to automatically discover representations needed for feature detection, prediction, classification, etc. using layers of processing. Deep learning techniques include, but are not limited to, artificial neural network or multilayer perceptron (MLP).

Machine learning models include supervised, semi-supervised, and unsupervised learning models. In a supervised learning model, the model learns a function that maps an input (also known as feature or features) to an output (also known as target or target) during training with a labeled data set (or dataset). In an unsupervised learning model, the model learns a function that maps an input (also known as feature or features) to an output (also known as target or target) during training with an unlabeled data set. In a semi-supervised model, the model learns a function that maps an input (also known as feature or features) to an output (also known as target or target) during training with both labeled and unlabeled data.

### Neural Networks

An artificial neural network (ANN) is a computing system including a plurality of interconnected neurons (e.g., also referred to as “nodes”). This disclosure contemplates that the nodes can be implemented using a computing device (e.g., a processing unit and memory as described herein). The nodes can be arranged in a plurality of layers such as input layer, output layer, and optionally one or more hidden layers. An ANN having hidden layers can be referred to as deep neural network or multilayer perceptron (MLP). Each node is connected to one or more other nodes in the ANN. For example, each layer is made of a plurality of nodes, where each node is connected to all nodes in the previous layer. The nodes in a given layer are not interconnected with one another, i.e., the nodes in a given layer function independently of one another. As used herein, nodes in the input layer receive data from outside of the ANN, nodes in the hidden layer(s) modify the data between the input and output layers, and nodes in the output layer provide the results. Each node is configured to receive an input, implement an activation function (e.g., binary step, linear, sigmoid, tan H, or rectified linear unit (ReLU) function), and provide an output in accordance with the activation function. Additionally, each node is associated with a respective weight. ANNs are trained with a dataset to maximize or minimize an objective function. In some implementations, the objective function is a cost function, which is a measure of the ANN's performance (e.g., error such as L1 or L2 loss) during training, and the training algorithm tunes the node weights and/or bias to minimize the cost function. This disclosure contemplates that any algorithm that finds the maximum or minimum of the objective function can be used for training the ANN. Training algorithms for ANNs include, but are not limited to, backpropagation. It should be understood that an artificial neural network is provided only as an example machine learning model. This disclosure contemplates that the machine learning model can be any supervised learning model, semi-supervised learning model, or unsupervised learning model. Optionally, the machine learning model is a deep learning model. Machine learning models are known in the art and are therefore not described in further detail herein.

A convolutional neural network (CNN) is a type of deep neural network that has been applied, for example, to image analysis applications. Unlike a traditional neural network, each layer in a CNN has a plurality of nodes arranged in three dimensions (width, height, depth). CNNs can include different types of layers, e.g., convolutional, pooling, and fully-connected (also referred to herein as “dense”) layers. A convolutional layer includes a set of filters and performs the bulk of the computations. A pooling layer is optionally inserted between convolutional layers to reduce the computational power and/or control overfitting (e.g., by downsampling). A fully-connected layer includes neurons, where each neuron is connected to all of the neurons in the previous layer. The layers are stacked similar to traditional neural networks. GCNNs are CNNs that have been adapted to work on structured datasets such as graphs.

### Other Supervised Learning Models:

A logistic regression (LR) classifier is a supervised classification model that uses the logistic function to predict the probability of a target, which can be used for classification. LR classifiers are trained with a data set (also referred to herein as a “dataset”) to maximize or minimize an objective function, for example a measure of the LR classifier's performance (e.g., error such as L1 or L2 loss), during training. This disclosure contemplates that any algorithm that finds the minimum of the cost function can be used. LR classifiers are known in the art and are therefore not described in further detail herein.

A Naïve Bayes' (NB) classifier is a supervised classification model that is based on Bayes' Theorem, which assumes independence among features (i.e., presence of one feature in a class is unrelated to presence of any other features). NB classifiers are trained with a data set by computing the conditional probability distribution of each feature given label and applying Bayes' Theorem to compute conditional probability distribution of a label given an observation. NB classifiers are known in the art and are therefore not described in further detail herein.

A k-NN classifier is a supervised classification model that classifies new data points based on similarity measures (e.g., distance functions). k-NN classifiers are trained with a data set (also referred to herein as a “dataset”) to maximize or minimize an objective function, for example a measure of the k-NN classifier's performance, during training. This disclosure contemplates that any algorithm that finds the maximum or minimum of the objective function can be used. k-NN classifiers are known in the art and are therefore not described in further detail herein.

A majority voting ensemble is a meta-classifier that combines a plurality of machine learning classifiers for classification via majority voting. In other words, the majority voting ensemble's final prediction (e.g., class label) is the one predicted most frequently by the member classification models. Majority voting ensembles are known in the art and are therefore not described in further detail herein.

### Simulation System

It should be appreciated that the logical operations described above can be implemented (1) as a sequence of computer-implemented acts or program modules running on a computing system and/or (2) as interconnected machine logic circuits or circuit modules within the computing system. The implementation is a matter of choice dependent on the performance and other requirements of the computing system. Accordingly, the logical operations described herein are referred to variously as state operations, acts, or modules. These operations, acts and/or modules can be implemented in software, in firmware, in special purpose digital logic, in hardware, and any combination thereof. It should also be appreciated that more or fewer operations can be performed than shown in the figures and described herein. These operations can also be performed in a different order than those described herein.

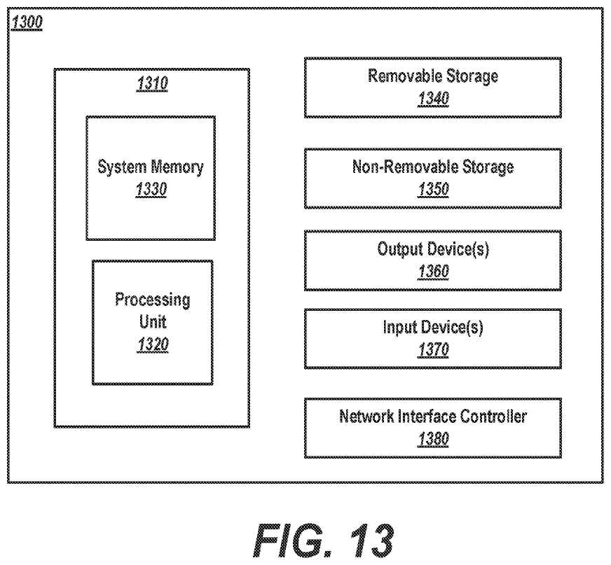

FIG. 13 shows an illustrative computer architecture for a computer system 1300 capable of executing the software components described herein for executing the machine-readable code of the exemplary ML-based method in the manner presented above. The computer architecture shown in FIG. 13 illustrates an example computer system configuration, and the computer 1300 can be utilized to execute any aspects of the components and/or modules presented herein described as executing on the Automated Related Question Recommender machine learning system or any components in communication therewith.

In an embodiment, the computing device 1300 may comprise two or more computers in communication with each other that collaborate to perform a task. For example, but not by way of limitation, an application may be partitioned in such a way as to permit concurrent and/or parallel processing of the instructions of the application. Alternatively, the data processed by the application may be partitioned in such a way as to permit concurrent and/or parallel processing of different portions of a data set by the two or more computers. In an embodiment, virtualization software may be employed by the computing device 1300 to provide the functionality of a number of servers that is not directly bound to the number of computers in the computing device 1300. For example, virtualization software may provide twenty virtual servers on four physical computers. In an embodiment, the functionality disclosed above may be provided by executing the application and/or applications in a cloud computing environment. Cloud computing may comprise providing computing services via a network connection using dynamically scalable computing resources. Cloud computing may be supported, at least in part, by virtualization software. A cloud computing environment may be established by an enterprise and/or may be hired on an as-needed basis from a third-party provider. Some cloud computing environments may comprise cloud computing resources owned and operated by the enterprise as well as cloud computing resources hired and/or leased from a third-party provider.

In its most basic configuration, computing device 1300 typically includes at least one processing unit 1320 and system memory 1330. Depending on the exact configuration and type of computing device, system memory 330 may be volatile (such as random-access memory (RAM)), non-volatile (such as read-only memory (ROM), flash memory, etc.), or some combination of the two. This most basic configuration is illustrated in FIG. 13 by dashed line 1310. The processing unit 1320 may be a standard programmable processor that performs arithmetic and logic operations necessary for operation of the computing device 1300. While only one processing unit 1320 is shown, multiple processors may be present. As used herein, processing unit and processor refers to a physical hardware device that executes encoded instructions for performing functions on inputs and creating outputs, including, for example, but not limited to, microprocessors (MCUs), microcontrollers, graphical processing units (GPUs), and application specific circuits (ASICs). Thus, while instructions may be discussed as executed by a processor, the instructions may be executed simultaneously, serially, or otherwise executed by one or multiple processors. The computing device 1300 may also include a bus or other communication mechanism for communicating information among various components of the computing device 1300.

Computing device 1300 may have additional features/functionality. For example, computing device 1300 may include additional storage such as removable storage 1340 and non-removable storage 1350 including, but not limited to, magnetic or optical disks or tapes. Computing device 1300 may also contain network connection(s) 280 that allow the device to communicate with other devices such as over the communication pathways described herein. The network connection(s) 1380 may take the form of modems, modem banks, Ethernet cards, universal serial bus (USB) interface cards, serial interfaces, token ring cards, fiber distributed data interface (FDDI) cards, wireless local area network (WLAN) cards, radio transceiver cards such as code division multiple access (CDMA), global system for mobile communications (GSM), long-term evolution (LTE), worldwide interoperability for microwave access (WiMAX), and/or other air interface protocol radio transceiver cards, and other well-known network devices. Computing device 1300 may also have input device(s) 1370 such as keyboards, keypads, switches, dials, mice, track balls, touch screens, voice recognizers, card readers, paper tape readers, or other well-known input devices. Output device(s) 1360 such as printers, video monitors, liquid crystal displays (LCDs), touch screen displays, displays, speakers, etc. may also be included. The additional devices may be connected to the bus in order to facilitate communication of data among the components of the computing device 1300. All these devices are well known in the art and need not be discussed at length here.

The processing unit 1320 may be configured to execute program code encoded in tangible, computer-readable media. Tangible, computer-readable media refers to any media that is capable of providing data that causes the computing device 1300 (i.e., a machine) to operate in a particular fashion. Various computer-readable media may be utilized to provide instructions to the processing unit 1320 for execution. Example tangible, computer-readable media may include, but is not limited to, volatile media, non-volatile media, removable media and non-removable media implemented in any method or technology for storage of information such as computer readable instructions, data structures, program modules or other data. System memory 1330, removable storage 1340, and non-removable storage 1350 are all examples of tangible, computer storage media. Example tangible, computer-readable recording media include, but are not limited to, an integrated circuit (e.g., field-programmable gate array or application-specific IC), a hard disk, an optical disk, a magneto-optical disk, a floppy disk, a magnetic tape, a holographic storage medium, a solid-state device, RAM, ROM, electrically erasable program read-only memory (EEPROM), flash memory or other memory technology, CD-ROM, digital versatile disks (DVD) or other optical storage, magnetic cassettes, magnetic tape, magnetic disk storage or other magnetic storage devices.

In light of the above, it should be appreciated that many types of physical transformations take place in the computer architecture 200 in order to store and execute the software components presented herein. It also should be appreciated that the computer architecture 200 may include other types of computing devices, including hand-held computers, embedded computer systems, personal digital assistants, and other types of computing devices known to those skilled in the art. It is also contemplated that the computer architecture 1300 may not include all of the components shown in FIG. 13, may include other components that are not explicitly shown in FIG. 13, or may utilize an architecture different than that shown in FIG. 13.

In an example implementation, the processing unit 1320 may execute program code stored in the system memory 1330. For example, the bus may carry data to the system memory 230, from which the processing unit 1320 receives and executes instructions. The data received by the system memory 1330 may optionally be stored on the removable storage 1340 or the non-removable storage 1350 before or after execution by the processing unit 1320.

It should be understood that the various techniques described herein may be implemented in connection with hardware or software or, where appropriate, with a combination thereof. Thus, the methods and apparatuses of the presently disclosed subject matter, or certain aspects or portions thereof, may take the form of program code (i.e., instructions) embodied in tangible media, such as floppy diskettes, CD-ROMs, hard drives, or any other machine-readable storage medium wherein, when the program code is loaded into and executed by a machine, such as a computing device, the machine becomes an apparatus for practicing the presently disclosed subject matter. In the case of program code execution on programmable computers, the computing device generally includes a processor, a storage medium readable by the processor (including volatile and non-volatile memory and/or storage elements), at least one input device, and at least one output device. One or more programs may implement or utilize the processes described in connection with the presently disclosed subject matter, e.g., through the use of an application programming interface (API), reusable controls, or the like. Such programs may be implemented in a high-level procedural or object-oriented programming language to communicate with a computer system. However, the program(s) can be implemented in assembly or machine language, if desired. In any case, the language may be a compiled or interpreted language and it may be combined with hardware implementations.

Some references, which may include various patents, patent applications, and publications, are cited in a reference list and discussed in the disclosure provided herein. The citation and/or discussion of such references is provided merely to clarify the description of the present disclosure and is not an admission that any such reference is “prior art” to any aspects of the present disclosure described herein. In terms of notation, “[n]” corresponds to the n^{th} reference in the list. All references cited and discussed in this specification are incorporated herein by reference in their entireties and to the same extent as if each reference was individually incorporated by reference.

Although example embodiments of the present disclosure are explained in some instances in detail herein, it is to be understood that other embodiments are contemplated. Accordingly, it is not intended that the present disclosure be limited in its scope to the details of construction and arrangement of components set forth in the following description or illustrated in the drawings. The present disclosure is capable of other embodiments and of being practiced or carried out in various ways.

It must also be noted that, as used in the specification and the appended claims, the singular forms “a,” “an,” and “the” include plural referents unless the context clearly dictates otherwise. Ranges may be expressed herein as from “about” or “5 approximately” one particular value and/or to “about” or “approximately” another particular value. When such a range is expressed, other exemplary embodiments include from the one particular value and/or to the other particular value.

By “comprising” or “containing” or “including” is meant that at least the name compound, element, particle, or method step is present in the composition or article or method, but does not exclude the presence of other compounds, materials, particles, method steps, even if the other such compounds, material, particles, method steps have the same function as what is named.

In describing example embodiments, terminology will be resorted to for the sake of clarity. It is intended that each term contemplates its broadest meaning as understood by those skilled in the art and includes all technical equivalents that operate in a similar manner to accomplish a similar purpose. It is also to be understood that the mention of one or more steps of a method does not preclude the presence of additional method steps or intervening method steps between those steps expressly identified. Steps of a method may be performed in a different order than those described herein without departing from the scope of the present disclosure. Similarly, it is also to be understood that the mention of one or more components in a device or system does not preclude the presence of additional components or intervening components between those components expressly identified.

The term “about,” as used herein, means approximately, in the region of, roughly, or around. When the term “about” is used in conjunction with a numerical range, it modifies that range by extending the boundaries above and below the numerical values set forth. In general, the term “about” is used herein to modify a numerical value above and below the stated value by a variance of 10%. In one aspect, the term “about” means plus or minus 10% of the numerical value of the number with which it is being used. Therefore, about 50% means in the range of 45%-55%. Numerical ranges recited herein by endpoints include all numbers and fractions subsumed within that range (e.g., 1 to 5 includes 1, 1.5, 2, 2.75, 3, 3.90, 4, 4.24, and 5).

Similarly, numerical ranges recited herein by endpoints include subranges subsumed within that range (e.g., 1 to 5 includes 1-1.5, 1.5-2, 2-2.75, 2.75-3, 3-3.90, 3.90-4, 4-4.24, 4.24-5, 2-5, 3-5, 1-4, and 2-4). It is also to be understood that all numbers and fractions thereof are presumed to be modified by the term “about.”

The following patents, applications, and publications as listed below and throughout this document are hereby incorporated by reference in their entirety herein.
[1] Fane, A. G.; Wang, R.; Hu, M. X., Synthetic Membranes for Water Purification: Status and Future. Angewandte Chemie International Edition 2015, 54, (11), 3368-3386.
[2] Elimelech, M.; Phillip, W. A., The Future of Seawater Desalination: Energy, Technology, and the Environment. Science 2011, 333, (6043), 712-717.
[3] Zhao, Y.; Tong, T.; Wang, X.; Lin, S.; Reid, E. M.; Chen, Y., Differentiating Solutes with Precise Nanofiltration for Next Generation Environmental Separations: A Review. Environmental Science & Technology 2021, 55, (3), 1359-1376.
[4] Wang, R.; Zhang, J.; Tang, C. Y.; Lin, S., Understanding Selectivity in Solute-Solute Separation: Definitions, Measurements, and Comparability. Environmental Science & Technology 2022.
[5] Chandra, V. & Kim, K. S. Highly selective adsorption of Hg2+ by a polypyrrole-reduced graphene oxide composite. Chemical Communications 47, 3942-3944, doi:10.1039/C1CC00005E (2011).
[6] Mueller, T., Kusne, A. G. & Ramprasad, R. Machine learning in materials science: Recent progress and emerging applications. Reviews in Computational Chemistry 29, 186-273 (2016).
[7] Lee, S. & Kim, J. Prediction of Nanofiltration and Reverse-Osmosis-Membrane Rejection of Organic Compounds Using Random Forest Model. Journal of Environmental Engineering 146, 04020127, doi:doi: 10.1061/(ASCE)EE.1943-7870.0001806 (2020).
[8] Goebel, R. & Skiborowski, M. Machine-based learning of predictive models in organic solvent nanofiltration: Pure and mixed solvent flux. Separation and Purification Technology 237, 116363 (2020).
[9] Goebel, R., Glaser, T. & Skiborowski, M. Machine-based learning of predictive models in organic solvent nanofiltration: Solute rejection in pure and mixed solvents. Separation and Purification Technology 248, 117046 (2020).
[10] Fetanat, M. et al. Machine learning for designing of thin-film nanocomposite membrane. Separation and Purification Technology, 118383, doi:https://doi.org/10.1016/j.seppur 2021.118383 (2021).
[11] Hu, J. et al. Artificial intelligence for performance prediction of organic solvent nanofiltration membranes. Journal of Membrane Science 619, 118513 (2021).
[12] Zhang, Z. et al. Deep spatial representation learning of polyamide nanofiltration membranes. Journal of Membrane Science 620, 118910 (2021).
[13] Yeo, C. S. H., Xie, Q., Wang, X. & Zhang, S. Understanding and optimization of thin film nanocomposite membranes for reverse osmosis with machine learning. Journal of Membrane Science 606, 118135 (2020).
[14] Barnett, J. W. et al. Designing exceptional gas-separation polymer membranes using machine learning. Science Advances 6, eaaz4301, doi:10.1126/sciadv.aaz4301 (2020).
[15] Otsuka, S., Kuwajima, I., Hosoya, J., Xu, Y. & Yamazaki, M. in 2011 International Conference on Emerging Intelligent Data and Web Technologies. 22-29.
[16] Tang, C. et al. Robust graph regularized unsupervised feature selection. Expert Systems with Applications 96, 64-76 (2018).
[17] Bien, J., Taylor, J. & Tibshirani, R. A lasso for hierarchical interactions. Annals of statistics 41, 1111 (2013).
[18] Li, C. & Li, H. Variable selection and regression analysis for graph-structured covariates with an application to genomics. The annals of applied statistics 4, 1498 (2010).
[19] Elimelech, M.; Phillip, W. A. The Future of Seawater Desalination: Energy, Technology, and the Environment. Science 2011, 333, 712-717.
[20] Fane, A. G.; Wang, R.; Hu, M. X. Synthetic membranes for water purification: status and future. Angew. Chem., Int. Ed. 2015, 54, 3368-3386.
[21] Wilf, M.; Alt, S. Application of low fouling RO membrane elements for reclamation of municipal wastewater. Desalination 2000, 132, 11-19.
[22] Bes-Piá, A.; Cuartas-Uribe, B.; Mendoza-Roca, J.; Galiana-Aleixandre, M.; Iborra-Clar, M.; Alcaina-Miranda, M. Pickling wastewater reclamation by means of nanofiltration. Desalination 2008, 221, 225-233.
[23] Zhao, Y.; Tong, T.; Wang, X.; Lin, S.; Reid, E. M.; Chen, Y. Differentiating Solutes with Precise Nanofiltration for Next Generation Environmental Separations: A Review. Environ. Sci. Technol. 2021, 55, 1359-1376.
[24] Blocher, C.; Niewersch, C.; Melin, T. Phosphorus recovery from sewage sludge with a hybrid process of low pressure wet oxidation and nanofiltration. Water Res. 2012, 46, 2009-2019.
[25] Gin, D. L.; Noble, R. D. Designing the next generation of chemical separation membranes. Science 2011, 332, 674-676.
[26] Marchetti, P.; Jimenez Solomon, M. F.; Szekely, G.; Livingston, A. G. Molecular separation with organic solvent nanofiltration: a critical review. Chem. Rev. 2014, 114, 10735-10806.
[27] Geise, G. M.; Park, H. B.; Sagle, A. C.; Freeman, B. D.; McGrath, J. E. Water permeability and water/salt selectivity tradeoff in polymers for desalination. J. Membr. Sci. 2011, 369, 130-138.
[28] Yang, Z.; Guo, H.; Tang, C. Y. The upper bound of thin-film composite (TFC) polyamide membranes for desalination. J. Membr. Sci. 2019, 590, No. 117297.
[29] Lau, W.; Gray, S.; Matsuura, T.; Emadzadeh, D.; Chen, J. P.; Ismail, A. A review on polyamide thin film nanocomposite (TFN) membranes: History, applications, challenges and approaches. Water Res. 2015, 80, 306-324.
[30] Yang, Z.; Sun, P.-F.; Li, X.; Gan, B.; Wang, L.; Song, X.; Park, H.-D.; Tang, C. Y. A Critical Review on Thin-Film Nanocomposite Membranes with Interlayered Structure: Mechanisms, Recent Developments, and Environmental Applications. Environ. Sci. Technol. 2020, 54, 15563-15583.
[31] Lee, S.; Kim, J. Prediction of Nanofiltration and Reverse-Osmosis-Membrane Rejection of Organic Compounds Using Random Forest Model. J. Environ. Eng. 2020, 146, No. 04020127.
[32] Goebel, R.; Skiborowski, M. Machine-based learning of predictive models in organic solvent nanofiltration: Pure and mixed solvent flux. Sep. Purif Technol. 2020, 237, No. 116363.
[33] Goebel, R.; Glaser, T.; Skiborowski, M. Machine-based learning of predictive models in organic solvent nanofiltration: Solute rejection in pure and mixed solvents. Sep. Purif Technol. 2020, 248, No. 117046.
[34] Fetanat, M.; Keshtiara, M.; Keyikoglu, R.; Khataee, A.; Daiyan, R.; Razmjou, A. Machine learning for designing of thin-film nanocomposite membrane. Sep. Purif. Technol. 2021, 270, No. 118383.
[35] Hu, J.; Kim, C.; Halasz, P.; Kim, J. F.; Kim, J.; Szekely, G. Artificial intelligence for performance prediction of organic solvent nanofiltration membranes. J. Membr. Sci. 2021, 619, No. 118513.
[36] Yeo, C. S. H.; Xie, Q.; Wang, X.; Zhang, S. Understanding and optimization of thin film nanocomposite membranes for reverse osmosis with machine learning. J. Membr. Sci. 2020, 606, No. 118135.
[37] Fetanat, M.; Keshtiara, M.; Low, Z.-X.; Keyikoglu, R.; Khataee, A.; Orooji, Y.; Chen, V.; Leslie, G.; Razmjou, A. Machine Learning for Advanced Design of Nanocomposite Ultrafiltration Membranes. Ind. Eng. Chem. Res. 2021, 60, 5236-5250.
[38] Barnett, J. W.; Bilchak, C. R.; Wang, Y.; Benicewicz, B. C.; Murdock, L. A.; Bereau, T.; Kumar, S. K. Designing exceptional gasseparation polymer membranes using machine learning. Sci. Adv. 2020, 6, No. eaaz4301.
[39] Pelikan, M. Bayesian Optimization Algorithm. In Hierarchical Bayesian Optimization Algorithm; Springer, 2005; pp 31-48.
[40] Snoek, J.; Larochelle, H.; Adams, R. P. Practical Bayesian optimization of machine learning algorithms. 2012, arXiv:1206.2944. arXiv.org e-Printarchive. https://arvix.org/abs/1206.2944.
[41] Wu, J.; Chen, X.-Y.; Zhang, H.; Xiong, L.-D.; Lei, H.; Deng, S.-H. Hyperparameter optimization for machine learning models based on Bayesian optimization. J. Electron. Sci. Technol. 2019, 17, 26-40.
[42] Victoria, A. H.; Maragatham, G. Automatic tuning of hyperparameters using Bayesian optimization. Evol. Syst. 2020, 12, 217-223.
[43] Griffiths, R.-R.; Hernindez-Lobato, J. M. Constrained Bayesian optimization for automatic chemical design using variational autoencoders. Chem. Sci. 2020, 11, 577-586.
[44] Shields, B. J.; Stevens, J.; Li, J.; Parasram, M.; Damani, F.; Alvarado, J. I. M.; Janey, J. M.; Adams, R. P.; Doyle, A. G. Bayesian reaction optimization as a tool for chemical synthesis. Nature 2021, 590, 89-96.
[45] Häse, F.; Roch, L. M.; Kreisbeck, C.; Aspuru-Guzik, A. Phoenics: a Bayesian optimizer for chemistry. ACS Cent. Sci. 2018, 4, 1134-1145.
[46] Liu, T.; Liu, L.; Cui, F.; Ding, F.; Zhang, Q.; Li, Y. Predicting the performance of polyvinylidene fluoride, polyethersulfone and polysulfone filtration membranes using machine learning. J. Mater. Chem. A 2020, 8, 21862-21871.
[47] Chen, T. In Guestrin, C. Xgboost: A Scalable Tree Boosting System, Proceedings of the 22Nd ACM SIGKDD International Conference on Knowledge Discovery and Data Mining (New York, NY, USA, 2016), KDD '16, ACM, 2016; 2016; pp 785-794.
[48] Dorogush, A. V.; Ershov, V.; Gulin, A. CatBoost: gradient boosting with categorical features support. 2018, arXiv:1810.11363. arXiv.org e-Printarchive. https://arvix.org/abs/1810.11363
[49] Yap, C. W. PaDEL-descriptor: An open source software to calculate molecular descriptors and fingerprints. J. Comput. Chem. 2011, 32, 1466-1474.
[50] Moriwaki, H.; Tian, Y.-S.; Kawashita, N.; Takagi, T. Mordred: A Molecular Descriptor C alculator. J. Cheminf 2018, 10, No. 4.
[51] Zhong, S.; Hu, J.; Yu, X.; Zhang, H. Molecular image convolutional neural network (CNN) assisted QSAR models for predicting contaminant reactivity toward OH radicals: Transfer learning, data augmentation and model interpretation. Chem. Eng. J. 2021, 408, No. 127998.
[52] Kearnes, S.; McCloskey, K.; Berndl, M.; Pande, V.; Riley, P. Molecular graph convolutions: moving beyond fingerprints. J. Comput.-Aided Mol. Des. 2016, 30, 595-608.
[53] Rogers, D.; Hahn, M. Extended-connectivity fingerprints. J. Chem. Inf. Model. 2010, 50, 742-754.
[54] Yu, S.; Ma, M.; Liu, J.; Tao, J.; Liu, M.; Gao, C. Study on polyamide thin-film composite nanofiltration membrane by interfacial polymerization of polyvinylamine (PVAm) and isophthaloyl chloride (IPC). J. Membr. Sci. 2011, 379, 164-173.
[55] Tang, Y.-J.; Xu, Z.-L.; Huang, B.-Q.; Wei, Y.-M.; Yang, H. Novel polyamide thin-film composite nanofiltration membrane modified with poly(amidoamine) and SiO₂ gel. RSC Adv. 2016, 6, 45585-45594.
[56] Zhang, K.; Zhong, S.; Zhang, H. Predicting Aqueous Adsorption of Organic Compounds onto Biochars, Carbon Nanotubes, Granular Activated Carbons, and Resins with Machine Learning. Environ. Sci. Technol. 2020, 54, 7008-7018.
[57] Sundararajan, M.; Najmi, A. In The Many Shapley Values for Model Explanation, International Conference on Machine Learning, 2020; PMLR: 2020; pp 9269-9278.
[58] Merrick, L.; Taly, A. The Explanation Game: Explaining Machine Learning Models Using Shapley Values, International Cross-Domain Conference for Machine Learning and Knowledge Extraction, 2020; Springer, 2020; pp 17-38.
[59] Butina, D. Unsupervised Data Base Clustering Based on Daylight's Fingerprint and Tanimoto Similarity: A Fast and Automated Way To Cluster Small and Large Data Sets. J. Chem. Inf. Comput. Sci. 1999, 39, 747-750.
[60] Wang, R.; Lin, S. Pore model for nanofiltration: History, theoretical framework, key predictions, limitations, and prospects. J. Membr. Sci. 2021, 620, No. 118809.
[61] Mohammad, A. W.; Teow, Y.; Ang, W.; Chung, Y.; Oatley-Radcliffe, D.; Hilal, N. Nanofiltration membranes review: Recent advances and future prospects. Desalination 2015, 356, 226-254.
[62] https://polymer.nims.go.jp/en/.
[63] Lan, G. First-order and Stochastic Optimization Methods for Machine Learning; Springer, 2020.
[64] Fang, W.; Shi, L.; Wang, R. Mixed polyamide-based composite nanofiltration hollow fiber membranes with improved low-pressure water softening capability. J. Membr. Sci. 2014, 468, 52-61.
[65] Ahmad, A. L.; Ooi, B. S.; Mohammad, A. W.; Choudhury, J. P. Composite Nanofiltration Polyamide Membrane: A Study on the Diamine Ratio and Its Performance Evaluation. Ind. Eng. Chem. Res. 2004, 43, 8074-8082.
[66] Zhao, Y.; Tong, X.; Chen, Y. Fit-for-Purpose Design of Nanofiltration Membranes for Simultaneous Nutrient Recovery and Micropollutant Removal. Environ. Sci. Technol. 2021, 55, 3352-3361.
[67] Liang, Y.; Zhu, Y.; Liu, C.; Lee, K.-R.; Hung, W.-S.; Wang, Z.; Li, Y.; Elimelech, M.; Jin, J.; Lin, S. Polyamide nanofiltration membrane with highly uniform sub-nanometre pores for sub-1 Å precision separation. Nat. Commun. 2020, 11, No. 2015.
[68] Tang, C. Y.; Kwon, Y.-N.; Leckie, J. O. Effect of membrane chemistry and coating layer on physiochemical properties of thin film composite polyamide RO and NF membranes: II. Membrane physiochemical properties and their dependence on polyamide and coating layers. Desalination 2009, 242, 168-182.
[69] Ma, X.-H.; Yao, Z.-K.; Yang, Z.; Guo, H.; Xu, Z.-L.; Tang, C. Y.; Elimelech, M. Nanofoaming of Polyamide Desalination Membranes To Tune Permeability and Selectivity. Environ. Sci. Technol. Lett. 2018, 5, 123-130.
[70] Willcox, J. A.; Kim, H. J. Molecular dynamics study of water flow across multiple layers of pristine, oxidized, and mixed regions of graphene oxide. ACS Nano 2017, 11, 2187-2193.
[71] Dai, H.; Xu, Z.; Yang, X. Water permeation and ion rejection in layer-by-layer stacked graphene oxide nanochannels: a molecular dynamics simulation. J. Phys. Chem. C 2016, 120, 22585-22596.
[72] Jeong, N.; Chung, T.-h.; Tong, T. Predicting Micropollutant Removal by Reverse Osmosis and Nanofiltration Membranes: Is Machine Learning Viable?Environ. Sci. Technol. 2021, 55 (16), 11348-11359.
[73] Liu, T.; Liu, L.; Cui, F.; Ding, F.; Zhang, Q.; Li, Y. Predicting the performance of polyvinylidene fluoride, polyethersulfone and polysulfone filtration membranes using machine learning. Journal of Materials Chemistry A 2020, 8 (41), 21862-21871.
[74] Fetanat, M.; Keshtiara, M.; Low, Z.-X.; Keyikoglu, R.; Khataee, A.; Orooji, Y.; Chen, V.; Leslie, G.; Razmjou, A. Machine learning for advanced design of nanocomposite ultrafiltration membranes. Ind. Eng. Chem. Res. 2021, 60 (14), 5236-5250.
[75] Yang, S. D.; Ali, Z. A.; Kwon, H.; Wong, B. M. Predicting Complex Erosion Profiles in Steam Distribution Headers with Convolutional and Recurrent Neural Networks. Ind. Eng. Chem. Res. 2022, 61 (24), 8520-8529.
[76] Zhang, K.; Zhong, S.; Zhang, H. Predicting aqueous adsorption of organic compounds onto biochars, carbon nanotubes, granular activated carbons, and resins with machine learning. Environ. Sci. Technol. 2020, 54 (11), 7008-7018.
[77] Wu, G.; Gan, S.; Cui, L.; Xu, Y. Preparation and characterization of PES/TiO2 composite membranes. Appl. Surf Sci. 2008, 254 (21), 7080-7086.
[78] Bai, L.; Liu, Y.; Bossa, N.; Ding, A.; Ren, N.; Li, G.; Liang, H.; Wiesner, M. R. Incorporation of Cellulose Nanocrystals (CNCs) into the Polyamide Layer of Thin-Film Composite (TFC) Nanofiltration Membranes for Enhanced Separation Performance and Antifouling Properties. Environ. Sci. Technol. 2018, 52 (19), 11178-11187.
[79] Persson, K. M.; Gekas, V.; Tragirdh, G. Study of membrane compaction and its influence on ultrafiltration water permeability. J. Membr. Sci. 1995, 100 (2), 155-162.
[80] Demirel, E.; Zhang, B.; Papakyriakou, M.; Xia, S.; Chen, Y. Fe2O3 nanocomposite PVC membrane with enhanced properties and separation performance. J. Membr. Sci. 2017, 529, 170-184.
[81] Mehta, A.; Zydney, A. L. Permeability and selectivity analysis for ultrafiltration membranes. J. Membr. Sci. 2005, 249 (1), 245-249.
[82] Hołda, A. K.; Aernouts, B.; Saeys, W.; Vankelecom, I. F. J. Study of polymer concentration and evaporation time as phase inversion parameters for polysulfone-based SRNF membranes. J. Membr. Sci. 2013, 442, 196-205.
[83] Shen, J.-n.; Ruan, H.-m.; Wu, L.-g.; Gao, C.-j. Preparation and characterization of PES-SiO2 organic-inorganic composite ultrafiltration membrane for raw water pretreatment. Chemical engineering journal 2011, 168 (3), 1272-1278.
[84] Yan, L.; Li, Y. S.; Xiang, C. B.; Xianda, S. Effect of nano-sized Al2O3-particle addition on PVDF ultrafiltration membrane performance. J. Membr. Sci. 2006, 276 (1-2), 162-167.
[85] Guillen, G. R.; Farrell, T. P.; Kaner, R. B.; Hoek, E. M. V. Porestructure, hydrophilicity, and particle filtration characteristics of polyaniline-polysulfone ultrafiltration membranes. J. Mater. Chem. 2010, 20 (22), 4621-4628.
[86] Zheng, Q.-Z.; Wang, P.; Yang, Y.-N.; Cui, D.-J. The relationship between porosity and kinetics parameter of membrane formation in PSF ultrafiltration membrane. J. Membr. Sci. 2006, 286 (1-2), 7-11.
[87] Katsoufidou, K.; Yiantsios, S. G.; Karabelas, A. J. Experimental study of ultrafiltration membrane fouling by sodium alginate and flux recovery by backwashing. J. Membr. Sci. 2007, 300 (1), 137-146.
[88] Gao, H.; Zhong, S.; Zhang, W.; Igou, T; Berger, E.; Reid, E.; Zhao, Y; Lambeth, D.; Gan, L.; Afolabi, M. A.; Tong, Z.; Lan, G.; and Chen, Y., Revolutionizing Membrane Design Using Machine Learning-Bayesian Optimization, Environ. Sci. Technol. 2022 56 (4), 2572-2581.
[89] Gao, H.; Zhong, S.; Dangayach, R.; and Chen, Y., Understanding and Designing a High-Performance Ultrafiltration Membrane Using Machine Learning, Environ. Sci. Technol. 2023, DOI: 10.1021/acs.est.2c05404.

1. A method to predict candidate separation membranes having a set of desired polymer membrane properties comprising:
(a) retrieving one or more datasets of experimentally measured separation membrane properties, fabrication conditions, and operational conditions and related molecular descriptions;
(b) categorizing each entry of the dataset as one of a set of meaningful constraints;
(c) encoding the categorized dataset for use in a machine learning model;
(d) screening one or more algorithms for an optimal machine learning model, wherein screening comprises training a test machine learning model with one or more algorithms for encoding, machine learning, and feature scaling on a subset of the one or more datasets, and validating the trained test machine learning model by cross-validation on the trained test machine learning model on the subset of the one or more datasets;
(e) choosing an optimal machine learning model, wherein the optimal test machine learning model is defined by a coefficient of determination;
(f) optimizing hyperparameters of the optimal machine learning model using Bayesian optimization, wherein an optimization target is the set of desired polymer membrane properties;
(g) retraining the optimal machine learning model on the subset of the one or more datasets; and
(f) running the retrained, optimal machine learning model on another subset of the one or more datasets to predict candidate separation membranes having a set of desired polymer membrane properties.

2. The method of claim 1, further comprising:
(g) computing Shapely values for the set of desired membrane properties on the related molecular descriptions; and
(h) displaying the computed Shapely values.

3. The method of claim 1, wherein the one or more datasets comprises effective separation membrane properties under real operation conditions generated from the mechanistic constitutive model as input variables.

4. The method of claim 1, wherein the related molecular description is a Morgan fingerprint and is related to a monomer of the polymer membrane.

5. The method of claim 1, wherein the algorithms for machine learning are tree-based machine learning algorithms.

6. A system comprising:
a processor; and
a memory having instructions stored thereon, wherein execution of the instructions by the processor causes the processor to:
execute the following steps:
(a) retrieve one or more datasets of experimentally measured separation membrane properties, fabrication conditions, and operational conditions and related molecular descriptions;
(b) categorize each entry of the dataset as one of a set of meaningful constraints;
(c) encode the categorized dataset for use in a machine learning model;
(d) screen one or more algorithms for an optimal machine learning model, wherein screening comprises training a test machine learning model with one or more algorithms for encoding, machine learning, and feature scaling on a subset of the one or more datasets, and validating the trained test machine learning model by cross-validation on the trained test machine learning model on the subset of the one or more datasets;
(e) choose an optimal machine learning model, wherein the optimal test machine learning model is defined by a coefficient of determination;
(f) optimize hyperparameters of the optimal machine learning model using Bayesian optimization, wherein an optimization target is the set of desired polymer membrane properties;
(g) retrain the optimal machine learning model on the subset of the one or more datasets; and
(f) run the retrained, optimal machine learning model on another subset of the one or more datasets to predict candidate separation membranes having a set of desired polymer membrane properties.

7. The system of claim 6, further comprising the executing the steps:
(g) compute Shapely values for the set of desired membrane properties on the related molecular descriptions; and
(h) display the computed Shapely values.

8. The system of claim 6, wherein the execution of the instructions by the processor further causes the processor to:
execute a mechanistic constitutive model of the membrane material to predict/estimate its effective properties under testing or operating conditions.

9. The system of claim 6, wherein the execution of the instructions by the processor further causes the processor to:
execute the optimized machine learning model to predict/estimate membrane performances.

10. The system of claim 6, wherein the related molecular description is a Morgan fingerprint and is related to a monomer of the polymer membrane.

11. The system of claim 6, wherein the algorithms for machine learning are tree-based machine learning algorithms.

12. A non-transitory computer readable medium having instructions stored thereon, wherein execution of the instructions by a processor causes the processor to:
execute the following steps:
(a) retrieve one or more datasets of experimentally measured separation membrane properties, fabrication conditions, and operational conditions and related molecular descriptions;
(b) categorize each entry of the dataset as one of a set of meaningful constraints;
(c) encode the categorized dataset for use in a machine learning model;
(d) screen one or more algorithms for an optimal machine learning model, wherein screening comprises training a test machine learning model with one or more algorithms for encoding, machine learning, and feature scaling on a subset of the one or more datasets, and validating the trained test machine learning model by cross-validation on the trained test machine learning model on the subset of the one or more datasets;
(e) choose an optimal machine learning model, wherein the optimal test machine learning model is defined by a coefficient of determination;
(f) optimize hyperparameters of the optimal machine learning model using Bayesian optimization, wherein an optimization target is the set of desired polymer membrane properties;
(g) retrain the optimal machine learning model on the subset of the one or more datasets; and
(f) run the retrained, optimal machine learning model on another subset of the one or more datasets to predict candidate separation membranes having a set of desired polymer membrane properties.

13. The non-transitory computer readable medium of claim 12, further comprising the executing the steps:
(g) compute Shapely values for the set of desired membrane properties on the related molecular descriptions; and
(h) display the computed Shapely values.

14. The non-transitory computer readable medium of claim 12, wherein the execution of the instructions by the processor further causes the processor to:
execute a mechanistic constitutive model of the membrane material to predict/estimate its effective properties under testing or operating conditions.

15. The non-transitory computer readable medium of claim 12, wherein the execution of the instructions by the processor further causes the processor to:
execute the optimized machine learning model to predict/estimate membrane performances.

16. The non-transitory computer readable medium of claim 12, wherein the optimized machine learning model employs effective membrane properties under real operation conditions generated from the mechanistic constitutive model as input variables.

17. The non-transitory computer readable medium of claim 12, wherein the related molecular description is a Morgan fingerprint and is related to a monomer of the polymer membrane.

18. The non-transitory computer readable medium of claim 12, wherein the algorithms for machine learning are tree-based machine learning algorithms.

19. The system of claim 6, wherein the separation membranes are employed for resource recovery from wastewater.
